(19) United States
(12) Patent Application Publication
(10) Pub. No.: US 2018/0053911 A1
(43) Pub. Date: Feb. 22, 2018

(54) TRANSPARENT ELECTRODE, METHOD FOR MANUFACTURING TRANSPARENT ELECTRODE, AND ORGANIC ELECTROLUMINESCENCE ELEMENT

(71) Applicant: Konica Minolta, Inc., Tokyo (JP)

(72) Inventors: Kazuhiro YOSHIDA, Tachikawa-shi, Tokyo (JP); Shigeru KOJIMA, Hino-shi, Tokyo (JP); Takeshi HAKII, Sagamihara-shi, Kanagawa (JP); Shun FURUKAWA, Sagamihara-shi, Kanagawa (JP)

(21) Appl. No.: 15/556,842

(22) PCT Filed: Nov. 16, 2015
(86) PCT No.: PCT/JP2015/082092

§ 371 Date: Sep. 8, 2017

(30) Foreign Application Priority Data
Mar. 13, 2015 (JP) 2015-050159

(51) Int. Cl. H01L 51/52; H01L 51/00; H01L 51/56; H01B 5/14

(52) U.S. Cl. CPC H01L 51/5215; H01L 51/0022; H01L 51/56; H01L 2251/305; H01L 51/5209; H01L 2251/306; H01L 2251/308; H01B 5/14

(57) ABSTRACT

A transparent electrode includes a substrate, a conductive metal layer, a metal adhesion layer and a transparent conductive layer. The conductive metal layer is on the substrate. The metal adhesion layer is between the substrate and the conductive metal layer. The transparent conductive layer covers the substrate, the metal adhesion layer and the conductive metal layer. The conductive metal layer has a thin metal wire formed using a metal nanoparticle ink or a metal complex ink.

### TECHNOLOGICAL FIELD

The present invention relates to a transparent electrode, a method for manufacturing a transparent electrode and an organic electroluminescence element; to be specific, relates to a transparent electrode having low resistance and high storability, a method for manufacturing the transparent electrode and an organic electroluminescence element provided with the transparent electrode.

### BACKGROUND ART

With the recent growing demand for flat-screen television receivers, display technologies of various systems, including those making use of liquid crystal, plasma, organic electroluminescence (hereinafter may be called “organic EL”) and field emission, have been developed. For any of these displays of different display systems, a transparent electrode is an essential component. The transparent electrode is indispensable not only for television receivers but also for touchscreens, mobile phones, electronic paper, various solar cells and various electroluminescence controlelements.

In particular, organic EL elements used for illumination and highly efficient solar cells are required to have a large area. Hence, an electrode having low resistance is required. In addition, demands for stable use for a long period of time under a high temperature environment and for maintenance of flexibility have been increasing.

For example, there is described in Patent Document 1 a method of calcining, by infrared ray irradiation, thin metal wires printed using an ink containing silver nanoparticles, and its effectiveness is known. However, an electrode showing low resistance and further improvement in storability is required.

### RELATED ART DOCUMENTS

### Patent Documents

Patent Document 1: Japanese Patent Application Publication No. 2014-175560

### SUMMARY

### Problems to be Solved by the Invention

The present invention has been conceived in view of the above problems and circumstances, and its solutions are to provide a transparent electrode having low resistance and high storability, a method for manufacturing the transparent electrode, and an organic EL element provided with the transparent electrode.

### Means for Solving the Problems

In order to solve the problems, the causes and the like of the above problems have been investigated, and it has been found out that, by disposing a metal adhesion layer between a substrate and thin metal wires and further disposing a transparent conductive layer covering the substrate, the metal adhesion layer and the conductive metal layer, a transparent electrode having low resistance and high storability can be provided.

That is, the above problems left to the present invention are solved by the following means.

1. A transparent electrode including:

a substrate;

a conductive metal layer on the substrate;

a metal adhesion layer between the substrate and the conductive metal layer; and

a transparent conductive layer covering the substrate, the metal adhesion layer and the conductive metal layer, wherein

the conductive metal layer has a thin metal wire formed using a metal nanoparticle ink or a metal complex ink.

2. The transparent electrode according to item 1, wherein the conductive metal layer further has a plating layer covering the thin metal wire.

3. The transparent electrode according to item 1 or 2, wherein the thin metal wire is formed by printing.

4. The transparent electrode according to any one of items 1 to 3, wherein the thin metal wire is formed using an inkjet parallel line drawing method.

5. The transparent electrode according to any one of items 1 to 4, wherein the metal adhesion layer contains a nitrogen atom-containing compound.

6. The transparent electrode according to item 5, wherein polyurethane is contained as the nitrogen atom-containing compound.

7. The transparent electrode according to item 5 or 6, wherein

the metal adhesion layer is formed using a curable composition, and

the curable composition contains, as the mitogen atom-containing compound, an aromatic heterocyclic compound containing a nitrogen atom having an unshared electron pair uninvolved in aromaticity.

8. The transparent electrode according to any one of items 1 to 7, wherein the metal adhesion layer contains a vinyl polymer.

9. The transparent electrode according to any one of items 1 to 8, wherein the metal adhesion layer contains a coupling agent.

10. The transparent electrode according to any one of items 1 to 9, wherein the metal adhesion layer contains a metal oxide.

11. The transparent electrode according to item 10, wherein the metal adhesion layer further contains a mercapto group-containing compound.

12. The transparent electrode according to any one of items 1 to 11, wherein the transparent conductive layer contains a conductive polymer.

13. The transparent electrode according to any one of items 1 to 11, wherein the transparent conductive layer contains a transparent conductive metal oxide.

14. A method for manufacturing a transparent electrode, including:

forming a metal adhesion layer on a substrate;

forming a thin metal wire on the metal adhesion layer using a metal nanoparticle or metal complex ink, thereby forming a conductive metal layer; and

forming a transparent conductive layer on the substrate, the metal adhesion layer and the conductive metal layer.

15. An organic electroluminescence element including the transparent electrode according to any one of items 1 to 13.

### Advantageous Effects of the Invention

According to the present invention, there can be provided a transparent electrode having low resistance and high storability, a method for manufacturing the transparent electrode, and an organic electroluminescence element provided with the transparent electrode.

Although appearance mechanism or action mechanism of the effects of the present invention is not clear yet, it is conjectured as follows.

That is, disposing a metal adhesion layer between a substrate and a conductive metal layer improves adhesiveness of the substrate and the conductive metal layer, and prevents the conductive metal layer from separating during the manufacturing process before the conductive metal layer is covered with the transparent conductive layer or at the time of use, and accordingly can manufacture a transparent electrode having high storability. Further, metal particles of the conductive metal layer closely adhere to the substrate. This can reduce fine spaces which are considered to be a factor for increase in resistance, and accordingly can make the transparent electrode have low resistance. Still further, because concern about separation of the metal particles (e.g. Ag) of the conductive metal layer, which occurs together with evaporation of the solvent or the like when the conductive metal layer is treated at high intensity and high temperature, for example, subjected to light calcination or drying with an oven, is eliminated, further reduction in resistance of the transparent electrode can be expected.

### BRIEF DESCRIPTION OF THE DRAWINGS

FIG. 1 is a schematic diagram showing the structure of a transparent electrode of the present invention.

FIG. 2A is a schematic diagram of a thin metal wire formed of a nano-paste containing metal nanoparticles.

FIG. 2B is a schematic diagram of thin metal wires formed of a nano-paste containing metal nanoparticles.

FIG. 2C is a schematic diagram of thin metal wires formed of a nano-paste containing metal nanoparticles.

FIG. 2D is a schematic diagram of thin metal wires formed of a nano-paste containing metal nanoparticles.

FIG. 2E is a schematic diagram of thin metal wires formed of a nano-paste containing metal nanoparticles.

FIG. 2F is a schematic diagram of thin metal wires formed of a nano-paste containing metal nanoparticles.

FIG. 2G is a schematic diagram of thin metal wires formed of a nano-paste containing metal nanoparticles.

FIG. 3A is a schematic explanatory diagram to conceptually explain an example of a method for forming a parallel line pattern.

FIG. 3B is a schematic explanatory diagram to conceptually explain the example of the method for forming a parallel line pattern.

FIG. 3C is a schematic explanatory diagram to conceptually explain the example of the method for forming a parallel line pattern.

FIG. 4A is a schematic diagram to explain an example of a method for forming a mesh functional pattern.

FIG. 4B is a schematic diagram to explain the example of the method for forming a mesh functional pattern.

FIG. 5A is a schematic diagram to explain an example of the method for forming a mesh functional pattern.

FIG. 5B is a schematic diagram to explain the example of the method for forming a mesh functional pattern.

FIG. 6A is a schematic diagram to explain an example of the method for forming a mesh functional pattern.

FIG. 6B is a schematic diagram to explain the example of the method for forming a mesh functional pattern.

FIG. 6C is a schematic diagram to explain the example of the method for forming a mesh functional pattern.

FIG. 6D is a schematic diagram to explain the example of the method for forming a mesh functional pattern.

FIG. 7 is a schematic diagram showing a plated thin metal wire.

FIG. 8 is a schematic diagram showing a modification of the structure of the transparent electrode of the present invention.

FIG. 9 is a schematic diagram showing a modification of the structure of the transparent electrode of the present invention.

FIG. 10 is a schematic structure diagram of an organic electroluminescence element of the present invention.

### EMBODIMENTS FOR CARRYING OUT THE INVENTION

A transparent electrode of the present invention is a transparent electrode including: a substrate; a conductive metal layer on the substrate; a metal adhesion layer between the substrate and the conductive metal layer; and a transparent conductive layer covering the substrate, the metal adhesion layer and the conductive metal layer, wherein the conductive metal layer has a thin metal wire(s) formed using a metal nanoparticle ink or a metal complex ink. This feature is a technical feature common or corresponding to all the claims 1 to 15.

In the present invention, in terms of appearance of the effects of the present invention, preferably the conductive metal layer further has a plating layer covering the thin metal wire(s). The reason is considered as follows. Plating the thin metal wires can fill in fine spaces in the thin metal wires, reduce the area of contact of the thin metal wires with the transparent conductive layer when formed, and reduce roughness, and therefore can prevent deterioration such as oxidation in the thin metal wires.

Further, in the present invention, in terms of appearance of the effects of the present invention, preferably the thin metal wire(s) is formed by printing.

Further, in the present invention, because the conductive metal layer can be made thin, preferably the thin metal wire(s) is formed using an inkjet parallel line drawing method.

Further, in the present invention, in terms of appearance of the effects of the present invention, preferably the metal adhesion layer contains a nitrogen atom-containing compound.

Further, in the present invention, in terms of appearance of the effects of the present invention, preferably polyurethane is contained as the nitrogen atom-containing compound.

Further, in the present invention, preferably the metal adhesion layer is formed using a curable composition, and the curable composition contains, as the mitogen atom-containing compound, an aromatic heterocyclic compound containing a nitrogen atom having an unshared electron pair uninvolved in aromaticity. This can make the transparent electrode have lower resistance and higher storability.

Further, in the present invention, in terms of appearance of the effects of the present invention, preferably the metal adhesion layer contains a vinyl polymer.

Further, in the present invention, in terms of appearance of the effects of the present invention, preferably the metal adhesion layer contains a coupling agent.

Further, in the present invention, in terms of appearance of the effects of the present invention, preferably the metal adhesion layer contains a metal oxide.

Further, in the present invention, in terms of appearance of the effects of the present invention, preferably the metal adhesion layer further contains a mercapto group-containing compound.

Further, in the present invention, in terms of appearance of the effects of the present invention, preferably the transparent conductive layer contains a conductive polymer.

Further, in the present invention, in terms of appearance of the effects of the present invention, preferably the transparent conductive layer contains a transparent conductive metal oxide.

A method for manufacturing a transparent electrode, thereby manufacturing the transparent electrode of the present invention, includes: forming a metal adhesion layer on a substrate; forming a thin metal wire(s) on the metal adhesion layer using a metal nanoparticle or metal complex ink, thereby forming a conductive metal layer; and forming a transparent conductive layer on the substrate, the metal adhesion layer and the conductive metal layer. This can manufacture a transparent electrode having low resistance and high storability.

The transparent electrode of the present invention is suitably included in an organic electroluminescence element. This can provide an organic EL element having low resistance and high storability.

Hereinafter, the present invention is detailed. Note that, in this application, “- (to)” between numerical values is used to mean that the numerical values before and after the sign are inclusive as the lower limit and the upper limit. Further, preferred embodiments of the present invention may be carried out with appropriate changes as far as they do not depart from the scope of claims and the scope of their equivalents.

<<Structure of Transparent Electrode>>

A transparent electrode of the present invention is a transparent electrode including: a substrate; a conductive metal layer on the substrate; a metal adhesion layer between the substrate and the conductive metal layer; and a transparent conductive layer covering the substrate, the metal adhesion layer and the conductive metal layer, wherein the conductive metal layer has a thin metal wire(s) formed using a metal nanoparticle ink or a metal complex ink.

FIG. 1 shows the structure (a cross-sectional view) of a transparent electrode of the present invention.

As shown in FIG. 1, a transparent electrode 10 has a metal adhesion layer 16, a conductive metal layer 12 and a transparent conductive layer 15 on/over a substrate 11.

The conductive metal layer 12 has thin metal wires 13 and a plating layer 14 on the thin metal wires 13.

The transparent conductive layer 15 is disposed to cover the substrate 11, the metal adhesion layer 16 and the conductive metal layer 12.

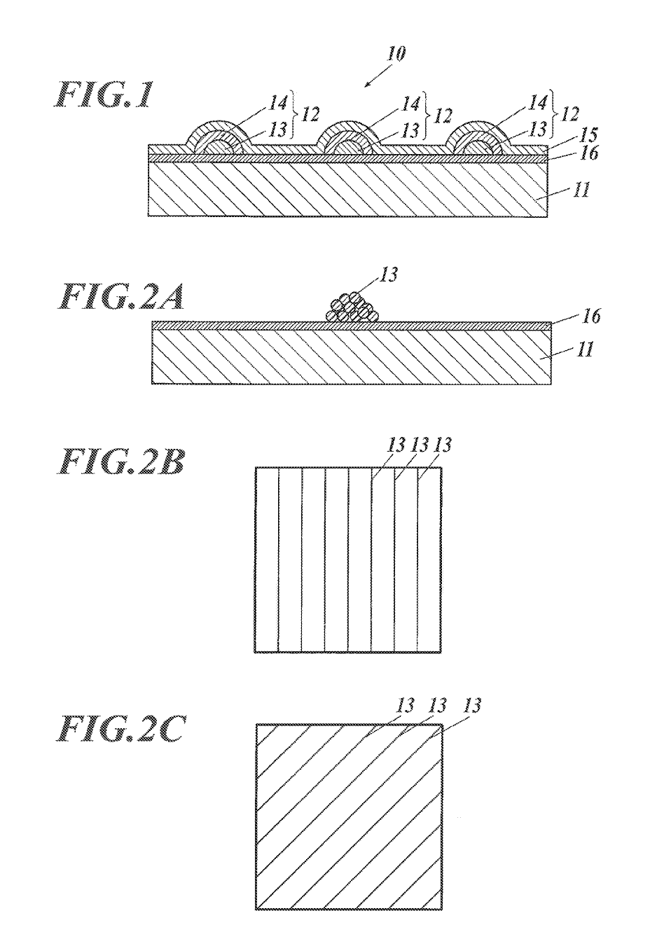

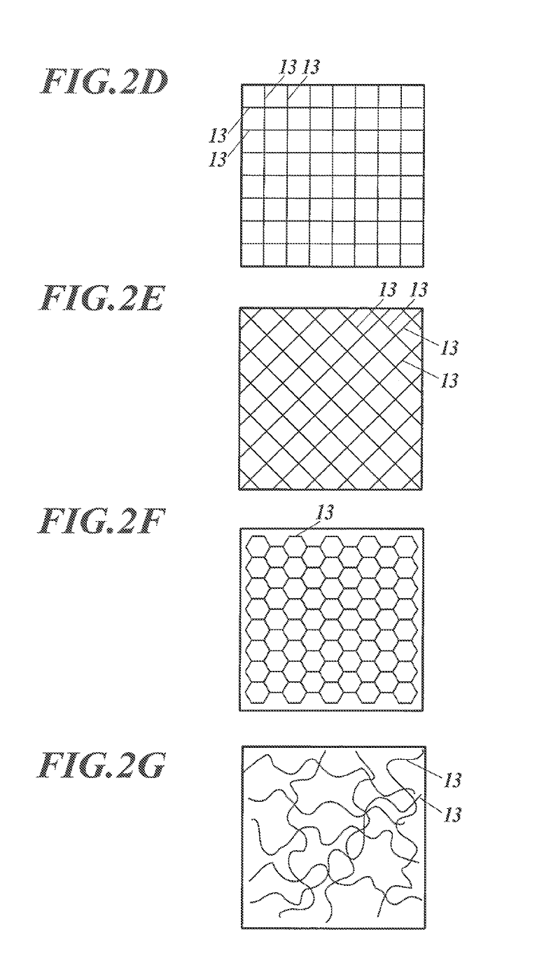

The thin metal wires 13 are composed by containing a metal nanoparticle ink or a metal complex ink as shown in FIG. 2A. FIG. 2A shows one thin metal wire formed using metal nanoparticles as an example, but can also be formed similarly using a metal complex ink.

In the example shown in FIG. 1, the conductive metal layer 12 has the thin metal wires 13 and the plating layer 14, but may not have the plating layer 14.

[Substrate]

As the substrate of the present invention, a transparent resin substrate having a total luminous transmittance in the visible light wavelength region of 80% or more determined by a method in conformity with JIS K 7361-1:1997 (Plastics—Determination of the Total Luminous Transmittance of Transparent Materials) is preferably used. One having a total luminous transmittance in the visible light wavelength region of 50% or more determined by a method in conformity with the above JIS standard is referred to as being transparent.

For the substrate, a material having excellent flexibility, a sufficiently small dielectric loss coefficient, and less absorption of microwaves than the conductive layer is preferable. As the substrate, it is preferable to use, for example, a transparent resin film in terms of productivity and properties such as lightness in weight and flexibility.

The transparent resin film usable by preference is not particularly limited, and can be suitably selected from among publicly-known ones in terms of material, shape, structure, thickness and so forth. Examples thereof include: polyester resin films of polyethylene terephthalate (PET), polyethylene naphthalate, modified polyester, etc.; polyethylene (PE) resin films; polypropylene (PP) resin films; polystyrene resin films; polyolefin resin films of cyclic olefin resin, etc.; vinyl resin films of polyvinyl chloride, polyvinylidene chloride, etc.; polyether ether ketone (PEEK) resin films; polysulfone (PSF) resin films; polyethersulfone (PES) resin films; polycarbonate (PC) resin films; polyamide resin films; polyimide resin films; acrylic resin films; and triacetylcellulose (TAC) resin films.

Any of the resin films having a total luminous transmittance of 80% or more can be preferably used as the substrate. In particular, in terms of transparency, infrared absorption, handleability, strength and costs, polyester resin films are preferable, and a biaxially oriented polyethylene terephthalate film and a biaxially oriented polyethylene naphthalate film are far preferable.

The substrate can be surface-treated or provided with an easy adhesion layer in order to ensure wettability and adhesiveness of an application liquid. Publicly-known technologies are usable for the surface treatment and the easy adhesion layer. Examples of the surface treatment include surface activation treatments such as corona discharge treatment, flame treatment, ultraviolet treatment, high frequency treatment, glow discharge treatment, activated plasma treatment and laser treatment.

Examples of the easy adhesion layer include polyester, polyamide, polyurethane, vinyl copolymers, butadiene copolymers, acrylic copolymers, vinylidene copolymers and epoxy copolymers. The easy adhesion layer may be composed of a single layer or, in order to improve adhesiveness, may be composed of two or more layers. On the front side or the back side of the substrate, a gas barrier layer which is composed of a coating composed of an inorganic substance or an organic substance or a gas barrier layer which is composed of a hybrid coating composed of an inorganic substance and an organic substance is preferably formed.

[Conductive Metal Layer]

The conductive metal layer is a layer having thin metal wires, preferably further having a plating layer on the thin metal wires.

It is also preferable to dispose a gas barrier layer between the substrate and the conductive metal layer. The gas barrier layer is described later.

[Thin Metal Wires]

The thin metal wires are formed on the substrate in a predetermined thin line pattern. The thin metal wires contain a metal nanoparticle ink or a metal complex ink.

Metal atom(s) contained in the metal nanoparticle ink or the metal complex ink is not particularly limited as far as it has conductivity. Examples thereof include metals such as gold, silver, copper, iron, cobalt, nickel and chromium, and alloys of these. In terms of conductivity, silver and copper are preferable, and silver is far preferable.

The metal nanoparticle ink is an ink containing metal nanoparticles, and may further contain a binder, a dispersant to disperse the metal nanoparticles, and/or the like, as needed.

The thin metal wires are formed on the substrate in a pattern having open parts so as to form a transparent electrode. The open parts are parts on the substrate the parts with no thin metal wire formed, and serve as translucent window parts.

The shape of the thin line pattern of the thin metal wires is not particularly limited. Preferable are, for example, a stripe pattern by which thin metal wires are striped, a lattice pattern by which thin metal wires are latticed, a hexagonal/honeycomb pattern by which thin metal wires are hexagonal/honeycomb, and a random network. In particular, in terms of small influence even if defects are generated in the thin metal wires, the lattice pattern, the honeycomb pattern and the random network are preferable, and the lattice pattern is most preferable. FIG. 2B to FIG. 2G are each a schematic diagram of a thin line pattern of thin metal wires on a substrate.

Examples of the method for forming thin metal wires in the stripe pattern or the lattice pattern include relief printing (letterpress), intaglio printing, screen printing and inkjet methods, thereby printing thin metal wires in a desired shape. Of the inkjet methods, printing using an inkjet parallel line drawing method is particularly preferable.

The inkjet parallel line drawing method is detailed later.

The open area ratio of the pattern of the thin metal wires is preferably 80% or more in terms of transparency. The open area ratio is a ratio of the translucent window parts, excluding the thin metal wires, which are not optically transparent, to the whole. For example, in the case where the thin metal wires are striped or latticed, the open area ratio of the stripe pattern having a line width of 100 μm and a line interval of 1 mm is about 90%.

The wire width of the thin metal wire(s) is preferably 10 to 200 μm. When the width of the thin metal wire(s) is 10 μm or more, a desired level of conductivity can be obtained, whereas when the width thereof is 200 μm or less, transparency can be prevented from decreasing. The height of the thin metal wire(s) is preferably 0.1 to 10 μm. When the height of the thin metal wire(s) is 0.1 μm or more, a desired level of conductivity can be obtained, whereas when the height thereof is 10 μm or less, current leakage and poor thickness distribution of a functional layer in forming an organic electronic device can be prevented from occurring.

The average particle size of the metal nanoparticles is preferably in a range from 1 to 100 nm, far preferably in a range from 1 to 50 nm and particularly preferably in a range from 1 to 30 nm.

The average particle size of the metal nanoparticles is obtained as follows: of metal nanoparticles observed under an electron microscope, 200 or more metal nanoparticles which are observable as circles, ovals, substantial circles or substantial ovals are observed at random; the particle size of each of the metal nanoparticles is obtained; and the number average value thereof is obtained. The particle size indicates the shortest distance among distances between two parallel lines between which the outer edge of a metal nanoparticle, which is observable as a circle, an oval, a substantial circle or a substantial oval, is sandwiched. When the average particle size is determined, the particle size which clearly represents a side face or the like of a metal nanoparticle is not included for the determination.

As a method for producing a dispersive substance containing metal nanoparticles, many proposals have been made and detailed, for example, in Japanese Patent Application Publication Nos. 2010-265543, 2011-68936, 2012-162767, 2012-144796, 2012-144795, 2012-52225, 2008-214591, 2007-200775, 2006-193594, 2012-119132 and 2011-153362 and Japanese Patent Application Publication (Translation of PCT Application) No. 2009-515023.

The random network structure can be formed, for example, by the method described in Japanese Patent Application Publication (Translation of PCT Application) No. 2005-530005, according to which a disordered network structure of conductive fine particles is spontaneously formed by application and drying of a liquid containing metal fine particles.

Surface resistivity of the thin metal wires is preferably 100 Ω/sq. or less and, for the large area described above, far preferably 20 Ω/sq. or less. The surface resistivity is measurable, for example, in conformity with JIS K 6911-2006, ASTM D257 or the like and is simply and easily measurable with a commercially-available surface resistivity meter.

It is preferable to carry out heat treatment on the thin metal wires within an extent of not damaging the film substrate. This is particularly preferable because metal nanoparticles or metal complexes are well fused with one another thereby, and conductivity of the thin metal wires increases.

As a method for the heat treatment, heating with an oven or heating with a hot plate, which is conventionally and generally carried out, can be used. Alternatively, local heat treatment may be used, and for that, flash pulse irradiation treatment, microwave treatment, plasma treatment, electron induction heating treatment, excimer laser irradiation treatment, ultraviolet treatment, infrared heater treatment, hot air heater treatment or the like can be used. As the heat treatment, heating with an oven or a hot plate and local heat treatment may be both carried out.

As the metal complex ink, any can be used as far as a metal forms a complex and is dispersed or dissolved in a solvent.

Examples of the solvent include ketocarboxylic acid, behenic acid, and stearic acid. Further, in Japanese Patent Application Publication (Translation of PCT Application) No. 2008-530001, an organic silver complex compound derived by reaction of a silver compound and an ammonium carbonate compound is cited, and this can be used too.

The metal complex ink may further contain, for example, an amine compound as a reductant.

As a method for producing a metal complex ink, any of the methods described, for example, in Japanese Patent Application Publication No. 2011-148759, Japanese Patent Application Publication (Translation of PCT Application) No. 2008-530001, and Japanese Patent Application Publication Nos. 2014-193991 and 2012-92299 can be used.

(Inkjet Parallel Line Drawing Method)

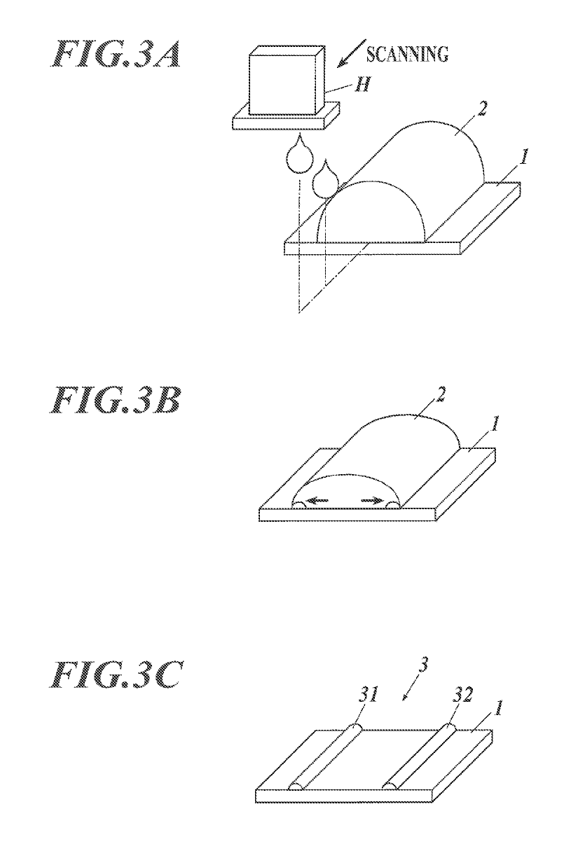

Hereinafter, the inkjet parallel line drawing method is described with reference to FIGS. 3A to 3C, FIGS. 4A and 4B, FIGS. 5A and 5B and FIGS. 6A to 6D.

As a basic principle, a phenomenon to accumulate, in drying a liquid containing a functional material applied on a substrate, the functional material contained in the liquid at the edge parts of the liquid selectively can be utilized. This phenomenon may be called coffee ring phenomenon or coffee stain phenomenon. Since the method is not limited to one for forming a ring-shaped pattern, the phenomenon may be called “coffee stain phenomenon” in the following explanation.

FIGS. 3A to 3C are schematic explanatory diagrams to conceptually explain an example of the method for forming a parallel line pattern, utilizing the basic principle.

In FIGS. 3A to 3C, “1” represents a base material, “2” represents a linear liquid containing a functional material, and “3” represents a coating formed by accumulating the functional material at the edges of the linear liquid 2 selectively (hereinafter, may be called “parallel line pattern”). Further, “H” represents an applier to apply a liquid onto the base material 1, and here constituted of a droplet discharge device. The droplet discharge device H can be constituted of, for example, an inkjet head(s) of an inkjet recording apparatus.

As shown in FIG. 3A, the droplet discharge device H discharges the liquid containing a functional material while the droplet discharge device H and the base material 1 scan relatively, and the droplets successively discharged are united on the base material, so that the linear liquid 2 containing the functional material is formed thereon.

Then, as shown in FIG. 3B, in evaporating and drying the linear liquid 2, coffee stain phenomenon is utilized so that the functional material is accumulated at the edges of the linear liquid 2 selectively.

Coffee stain phenomenon can be made to occur by setting conditions for drying the linear liquid 2.

That is, the linear liquid 2 on the base material 1 is dried faster at the edges than at the center part, and with the progress of drying, the solid content concentration reaches the saturating concentration, and local precipitation of the solid content occurs at the edges of the linear liquid 2.

This precipitated solid content settles the edges of the linear liquid 2, and prevents the linear liquid 2 from contracting in the width direction, which would be caused by the ensuing drying. This effect allows the liquid of the linear liquid 2 to form a convention current from the center part to the edges so as to compensate for the liquid lost by evaporation at the edges.

Because this convention current results from the settlement of the contact lines of the linear liquid 2 following the drying and difference between the amounts of evaporation at the center part and the edges of the linear liquid 2, the convention current changes according to the solid content concentration, the contact angle of the linear liquid 2 and the base material 1, the amount of the linear liquid 2, heating temperature of the base material 1, arrangement density of the linear liquid 2 and/or environmental factors such as temperature, humidity and air pressure, and therefore can be controlled by adjusting these.

As a result of that, as shown in FIG. 3C, the parallel line pattern 3 constituted of thin lines containing the functional material is formed on the base material 1. The parallel line pattern 3 formed from one line of the linear liquid 2 is constituted of a pair of thin lines 31, 32.

By applying the above method for forming the parallel line pattern, a mesh functional pattern constituted of the parallel line patterns which intersect with one another can be formed.

This mesh functional pattern is effective in realizing distribution of the functional material on the base material in a state in which low visibility is maintained.

In particular, line segments constituting the parallel line pattern formed as described above can realize a line width of several μm. This fine line width allows the mesh functional pattern not to be recognized with eyes of a person and to look like transparent even when the functional material itself is not transparent.

The shape of the thin line pattern of the functional material can be set according to the device which uses the functional material. In a touch sensor(s) used in a touchscreen, which is an example of the device, a transparent surface electrode(s) is used to detect a point touched with a finger or the like.

If, in the mesh functional pattern, a conductive material is used as the functional material, the pattern is preferably applicable to the transparent surface electrode or the like for a touchscreen or the like. In order to constitute a surface electrode or the like, the mesh functional pattern of the parallel line patterns different from one another in the forming direction is very effective in increasing the number of conductive paths.

An example of the method for forming the mesh functional pattern is the following method.

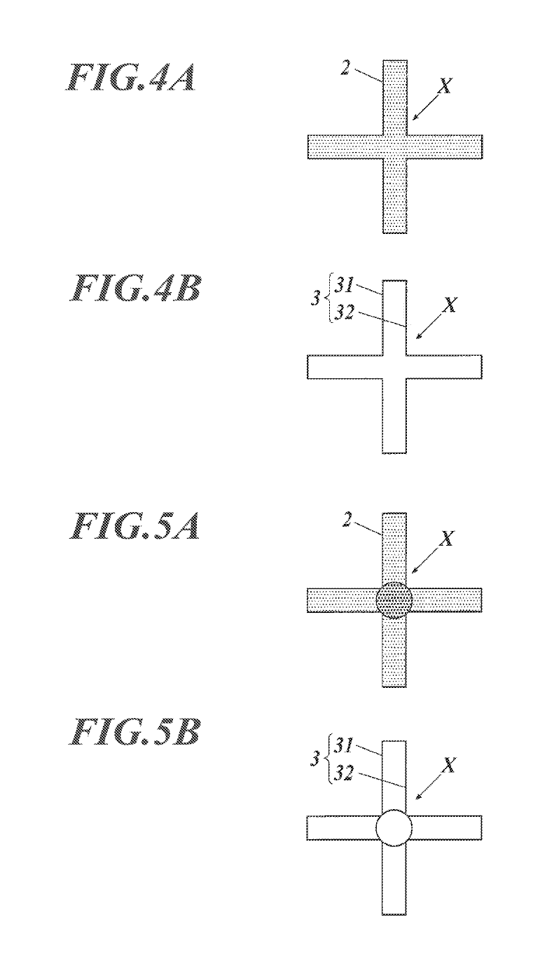

FIGS. 4A and 4B are explanatory diagrams to explain an example (reference example) of the method for forming a mesh functional pattern.

First, as shown in FIG. 4A, the linear liquid 2 is applied onto the base material 1 in such a way as to be meshed. That is, the linear liquid 2 is applied such that lines intersect at a crossing part X.

Next, the linear liquid 2 is dried, so that the mesh pattern of the parallel line patterns 3 can be formed as shown in FIG. 4B.

At the time, as a result of accumulation of the functional material contained in the linear liquid 2 at the edges, the line segments 31, 32 are discontinued at the crossing part X at which the parallel lines in different directions intersect with one another.

An example of the method for preventing the line segments 31, 32 from being discontinued at the crossing part X is the following method.

FIGS. 5A and 5B are explanatory diagrams to explain another example (reference example) of the method for forming a mesh functional pattern.

In this example, as shown in FIG. 5A, in the method shown in FIGS. 4A and 4B, the ink amount at the part of an intersection point formed of the linear liquid 2 is set larger than that at the other part(s).

As shown in FIG. 5B, this method can prevent the line segments 31, 32 from being discontinued at the crossing part X in the mesh pattern of the parallel line patterns 3.

At the time, because the ink amount to the crossing part X is increased, as shown in FIG. 5B, the crossing part X is ring-shaped and has a diameter larger than the distance between the line segments 31, 32.

Generating this ring-shaped part prevents the line segments 31, 32 from being discontinued, and is effective, for example, in making it easy to ensure conductivity. However, the ring-shaped part may be visible periodically, and it is understood that it has a limit in lower visibility.

Another example of the method for preventing the line segments 31, 32 from being discontinued at the crossing part X is the following method.

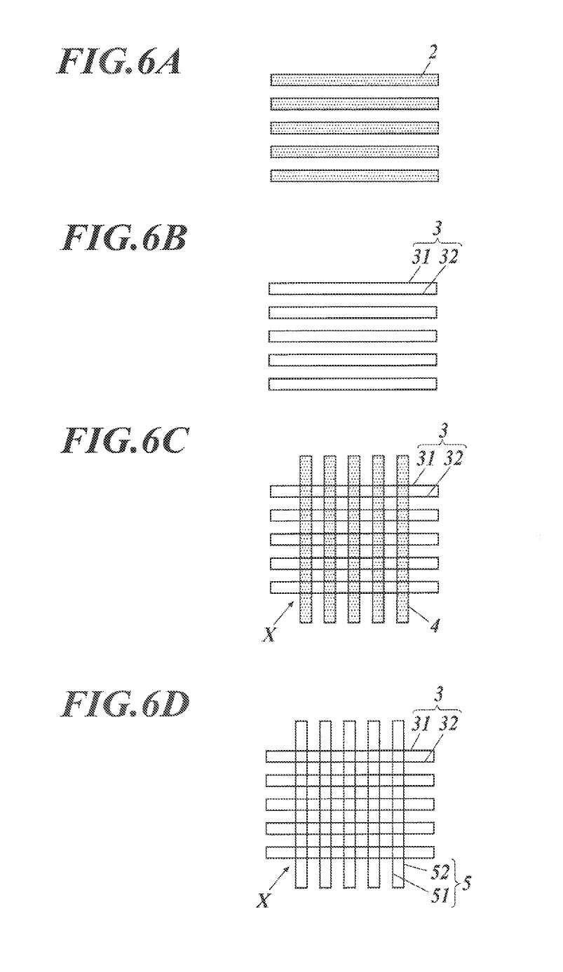

FIGS. 6A to 6D are explanatory diagrams to explain another example of the method for forming a mesh functional pattern.

First, as shown in FIG. 6A, the linear liquid 2 is applied in a first direction (the right-left direction in the figure).

In the step of drying this linear liquid 2, the functional material is accumulated at the edges selectively, so that first parallel line patterns 3 are formed as shown in FIG. 6B.

Next, as shown in FIG. 6C, a second linear liquid 4 is applied in a second direction (in this example, the direction at right angles with the first direction, namely, the up-down direction in the figure) different from the first direction. That is, the second linear liquid 4 is applied in such a way as to intersect with the first parallel line patterns 3.

In the step of drying this linear liquid 4, the functional material is accumulated at the edges selectively, so that second parallel line patterns 5 are formed as shown in FIG. 6D. The “51” and “52” represent line segments constituting each second parallel line pattern 5.

As described above, the mesh functional pattern constituted of the first parallel line patterns 3 and the second parallel line patterns 5 different from one another in the forming direction is formed.

This method can prevent the line segments 31, 32 and the line segments 51, 52 from being discontinued at the crossing parts X at which the parallel lines in different directions interest with one another.

[Plating Layer]

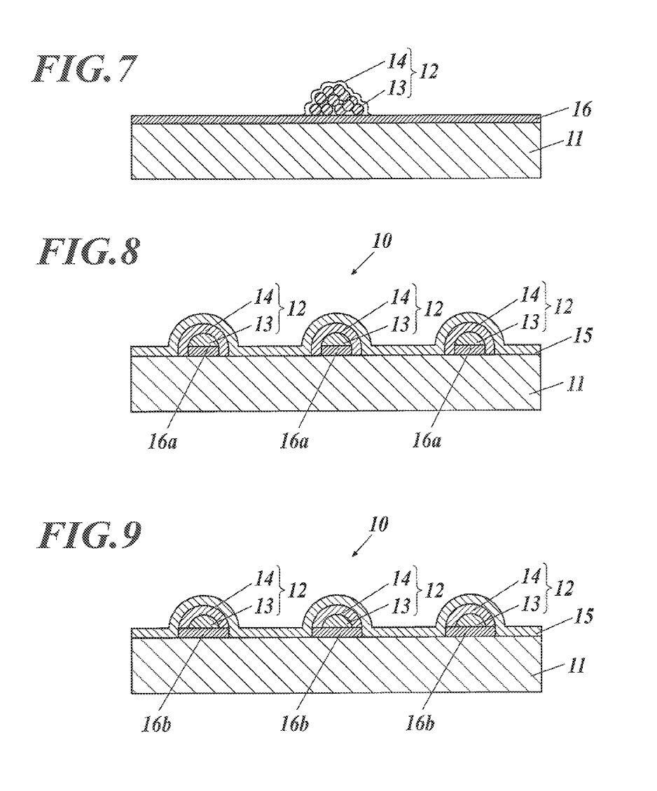

The plating layer 14 is formed on the thin metal wires 13, to be specific, formed to cover the thin metal wires 13 (see FIG. 7).

As a method for plating, there is a method of, after thin metal wires are formed on a substrate, applying a plating agent thereto in a desired shape by relief printing, intaglio printing, screen printing or the inkjet method(s), carrying out calcination and so forth as needed, and then carrying out electrolytic plating, electroless plating, or electrolytic plating after electroless plating, thereby plating the thin metal wires.

As the plating agent, for example, one in which plating nuclei, to be specific, conductive substance(s), are dispersed or the like in a solvent can be used.

Usable examples of the conductive substance as the plating nuclei include transition metals and their compounds. Of these, ionic transition metals are preferably used. For example, transition metals such as copper, silver, gold, nickel, palladium, platinum and cobalt are preferably used, and silver, gold and copper are far preferably used because they can form a conductive pattern which has low electric resistance and is resistant to corrosion.

As the conductive substance, it is preferable to use a particulate one having an average particle size of about 1 to 50 nm. This average particle size means the median particle diameter (D50), and is a value determined with a laser diffraction/scattering particle size distribution analyzer.

The content of the conductive substance such as metal to the total conductive ink is preferably in a range from 10 to 60 mass %.

As the plating agent, in addition to the above conductive substance, one or more types of oxides of the above metals and the metals surface-coated with organic substances and so forth can be used.

The metal oxides are normally in an inactive (insulating) state, but can be active (conductive), for example, by being treated with a reductant such as dimethylamine borane so as to expose the metals.

Examples of the metals surface-coated with organic substances include one composed of a metal in resin particles (organic substance) formed by emulsion polymerization or the like. These are normally in an inactive (insulating) state, but can be active (conductive), for example, by removing the organic substances with a laser or the like so as to expose the metals.

Further, examples of the solvent used for the plating agent include an aqueous medium usable for the conductive ink. Examples of the aqueous medium usable as the solvent include water, an organic solvent miscible with water, and a mixture of these. Examples of the organic solvent miscible with water include: alcohols such as methanol, ethanol, n-propanol and isopropanol; ketones such as acetone and methyl-ethyl-ketone; polyalkylene glycols such as ethylene glycol, diethylene glycol and propylene glycol; alkyl ethers of polyalkylene glycols; and lactams such as N-methyl-2-pyrrolidone. In the present invention, only water may be used, a mixture of water and an organic solvent miscible with water may be used, or only an organic solvent miscible with water may be used. In terms of safety and a load on the environment, only water or a mixture of water and an organic solvent miscible with water is preferable, and only water is particularly preferable.

Examples of the solvent such as the organic solvent, usable examples of the organic solvent, include: ketones such as acetone and methyl-ethyl-ketone; ethers such as tetrahydrofuran and dioxane; ester acetates such as ethyl acetate and butyl acetate; nitriles such as acetonitrile; and amides such as dimethylformamide and N-methylpyrrolidone. These can be used individually, or two or more types thereof can be used. Equivalents to these can also be used.

The step of electroless plating is a step for forming an electroless plating coating composed of a metal coating by making an electroless plating liquid contact the surface of the thin metal wires supporting the plating nuclei such as palladium or silver, thereby precipitating the metal such as copper contained in the electroless plating liquid.

As the electroless plating liquid, for example, one containing: a conductive substance composed of metal such as copper, nickel, chromium, cobalt or tin; a reductant; an aqueous medium; and a solvent such as an organic solvent can be used.

Usable examples of the reductant include dimethylamino borane, phosphinic acid, sodium phosphinate, dimethylamine borane, hydrazine, formaldehyde, sodium borohydride and phenols.

The electroless plating liquid may contain a complexing agent as needed. Examples thereof include: organic acids including: monocarboxylic acids such as acetic acid and formic acid; dicarboxylic acids such as malonic acid, succinic acid, adipic acid, maleic acid and fumaric acid; hydroxycarboxylic acids such as malic acid, lactic acid, glycolic acid, gluconic acid and citric acid; amino acids such as glycine, alanine, iminodiacetic acid, arginine, aspartic acid and glutamic acid; amino polycarboxylic acids such as iminodiacetic acid, nitrilotriacetic acid, ethylenediaminediacetic acid, ethylenediaminetetraacetic acid and diethylenetriaminepentaacetic acid; soluble salts (sodium, potassium salt, ammonium salt, etc.) of these organic acids; and amines including ethylenediamine, diethylenetriamine and triethylenetetramine.

The temperature of the electroless plating liquid in making the electroless plating liquid contact the surface of the thin metal wires supporting the plating nuclei in the plating agent is preferably in a range from about 20° C. to 98° C.

Further, the step of electrolytic plating is a step for forming an electrolytic plating coating (a metal coating) by energization in a state in which an electrolytic plating liquid contacts the surface of the thin metal wires supporting the plating nuclei or the surface of the electroless plating coating formed by the electroless plating, thereby precipitating the metal such as copper contained in the electrolytic plating liquid on the surface of the thin metal wires set to the negative pole or the surface of the electroless plating coating formed by the electroless plating.

As the electrolytic plating liquid, one containing: a conductive substance composed of metal such as copper, nickel, chromium, cobalt or tin; sulfuric acid or the like; and an aqueous medium can be used.

The temperature of the electrolytic plating liquid in making the electrolytic plating liquid contact the surface of the thin metal wires supporting the plating nuclei in the plating agent is preferably in a range from about 20° C. to 98° C.

[Metal Adhesion Layer]

The metal adhesion layer is disposed between the substrate and the conductive metal layer and can improve adhesiveness of the substrate and the conductive metal layer, and can reduce resistance and improve stability of the transparent electrode.

This metal adhesion layer contains, for example, a nitrogen atom-containing compound, a vinyl polymer, a coupling agent, a metal oxide and/or the like, which are described later. The materials contained in the metal adhesion layer are not limited to the above materials, and may be any as far as they can increase adhesiveness of the substrate and the conductive metal layer. The metal adhesion layer may contain one type of the above materials, or may contain two or more types thereof in combination.

The metal adhesion layer is, as shown in FIG. 1, disposed on the whole surface of the substrate, the surface on which the thin metal wires 3 and so forth are to be formed. Thus, the metal adhesion layer 16 can be formed at once on the whole surface of one side of the substrate 11, and can improve both adhesiveness of the substrate 11 and the thin metal wires 13 and adhesiveness of the substrate 11 and the plating layer 14. Thus, this is preferable in terms of easiness in manufacturing and storability of the transparent electrode.

The metal adhesion layer may be disposed on part(s) of the surface of the substrate 11, the surface on which the thin metal wires 13 and so forth are to be formed, as shown in FIG. 8 and FIG. 9. In the example shown in FIG. 8, a metal adhesion layer 16a is disposed only between the substrate 11 and each of the thin metal wires 13. This can reduce the used amount of the materials for forming the metal adhesion layer, and hence is preferable in terms of manufacturing costs. Further, in the example shown in FIG. 9, a metal adhesion layer 16b is formed only between the substrate 11 and each of the thin metal wires 13 and the plating layer 14 thereon. This can improve adhesiveness of not only the thin metal wires 13 but also the plating layer 14 to the substrate 11, and can reduce the used amount of the materials for the metal adhesion layer, and hence is preferable in terms of manufacturing costs and storability of the transparent electrode.

Thus, the metal adhesion layer is disposed at least between the substrate 11 and each of the thin metal wires 13, preferably between the substrate 11 and each of the thin metal wires 13 and the plating layer 14 thereon.

The thickness of the metal adhesion layer is appropriately set according to the materials contained in the metal adhesion layer, but preferably, for example, in a range from 50 nm to 5 μm.

The method for forming the metal adhesion layer is, as described below, appropriately selected according to the materials contained in the metal adhesion layer, but, if the metal adhesion layer is formed only between the substrate and each thin metal wire or only between the substrate and each thin metal wire and the plating layer thereon, for example, an inkjet method is preferable in terms of forming accuracy.

Hereinafter, those usable by preference as the materials for the metal adhesion layer are described.

(Nitrogen Atom-containing Compound)

The metal adhesion layer of the present invention preferably contains a nitrogen atom-containing compound.

Examples of the nitrogen atom-containing compound include: hexanediamine; isocyanate; polyamide; polyurethane; and an aromatic heterocyclic compound containing a nitrogen atom(s) having an unshared electron pair uninvolved in aromaticity. Of these, polyurethane and an aromatic heterocyclic compound containing a nitrogen atom(s) having an unshared electron pair uninvolved in aromaticity are preferable.

(Polyurethane)

The metal adhesion layer of the present invention preferably contains polyurethane as the nitrogen atom-containing compound.

Examples of the polyurethane include polyurethane having a polyether structure, polyurethane having a polycarbonate structure, and polyurethane having an aliphatic polyester structure.

The metal adhesion layer is preferably formed by application of a composition containing polyurethane and a medium.

Usable examples of the medium include various types of organic solvent and aqueous medium.

Usable examples of the organic solvent include toluene, ethyl acetate, and methyl-ethyl-ketone. Usable examples of the aqueous medium include water, an organic solvent miscible with water, and a mixture of these.

Examples of the organic solvent miscible with water include: alcohols such as methanol, ethanol, n-propanol, isopropanol, ethyl carbitol, ethyl cellosolve and butyl cellosolve; ketones such as acetone and methyl-ethyl-ketone; polyalkylene glycols such as ethylene glycol, diethylene glycol and propylene glycol; alkyl ethers of polyalkylene glycols; and lactams such as N-methyl-2-pyrrolidone.

As the medium, only water may be used, a mixture of water and an organic solvent miscible with water may be used, or only an organic solvent miscible with water may be used. In terms of safety and a load on the environment, only water or a mixture of water and an organic solvent miscible with water is preferable, and only water is particularly preferable.

If an aqueous medium is used as the medium, it is preferable to use a resin containing a hydrophilic group as the urethane resin in order to improve dispersion-in-water stability and storage stability.

Examples of the hydrophilic group include an anionic group, a cationic group and a nonionic group. Of these, a cationic group is far preferable.

Usable examples of the anionic group include a carboxy group, a carboxylate group, a sulfonic acid group and a sulfonate group. Of these, a carboxylate group or a sulfonate group formed by being partly or entirely neutralized by a basic compound is preferable in order to give the resin excellent dispersibility in water.

Examples of the basic compound usable for neutralization for the anionic group include: ammonia; organic amines such as trimethylamine, pyridine and morpholine; alkanolamines such as monoethanolamine; and metal basic compounds such as sodium, potassium, lithium and calcium. If a plating nuclear pattern is formed, the metal basic compounds may inhibit precipitation of plating, and therefore the above ammonia, organic amine(s) or alkanolamine(s) is preferably used as the basic compound.

If the above carboxylate group or sulfonate group is used as the anionic group, preferably it is present, to the whole resin, 50 to 2,000 mmol/kg in order to give the resin excellent dispersion-in-water stability.

Usable examples of the cationic group include a tertiary amino group.

Examples of acid usable for partial or total neutralization of the tertiary amino group include: organic acids such as acetic acid, propionic acid, lactic acid and maleic acid; sulfonic acids such as sulfonic acid and methanesulfonic acid; and inorganic acids such as hydrochloric acid, sulfuric acid, orthophosphoric acid and orthophosphorous acid. If a plating nuclear pattern is formed, chlorine and sulfur may inhibit precipitation of plating or the like, and therefore acetic acid, propionic acid, lactic acid, maleic acid or the like is preferably used.

Usable examples of the nonionic group include polyoxyalkylene groups such as a polyoxyethylene group, a polyoxypropylene group, a polyoxybutylene group, a poly(oxyethylene-oxypropylene) group, and a polyoxyethylene-polyoxypropylene group. Of these, a polyoxyalkylene group having an oxyethylene unit(s) is preferably used in order to further improve hydrophilicity.

In producing the polyurethane, an organic solvent can be used as a solvent.

Examples of the organic solvent include: ketones such as acetone and methyl-ethyl-ketone; ethers such as tetrahydrofuran and dioxane; ester acetates such as ethyl acetate and butyl acetate; nitriles such as acetonitrile; and amides such as dimethylformamide and N-methylpyrrolidone. These can be used individually, or two or more types thereof can be used.

It is preferable to remove the organic solvent by a distillation method or the like after producing the polyurethane. However, if one containing polyurethane and an organic solvent is used as the composition, the organic solvent used in producing the polyurethane may be used as the medium of the composition.

In terms of adhesiveness of the substrate and the conductive metal layer, the polyurethane has a weight average molecular weight of 5,000 or more as a must, preferably 500,000 or less, and far preferably 20,000 to 100,000.

(Cationic Group-Containing Polyurethane)

As the polyurethane, for example, cationic group-containing polyurethane is preferably used. The cationic group-containing polyurethane can be present in an aqueous medium by being stably dispersed or dissolved therein thanks to the hydrophilic group which is the cationic group.

The cationic group is preferable in order to give the (cationic group-containing) polyurethane excellent dispersion-in-water stability in an aqueous medium and also to give the metal adhesion layer of the present invention excellent adhesiveness.

The content of the cationic group is, to the whole amount of the cationic group-containing polyurethane, preferably 30 to 450 mmol/kg in total in order to achieve both excellent dispersion-in-water stability and excellent adhesiveness to the substrate, and far preferably 30 to 200 mmol/kg.

Usable examples of the cationic group include: amino groups such as a tertiary amino group; and functional groups formed by neutralization or quaternization of the above with an acid group-containing compound or a quaternizing agent or the like. Of these, a cationic group formed by neutralization of an amino group preferably with an organic acid having a boiling point of 300° C. or less and far preferably with acetic acid is preferable for very excellent adhesiveness to the substrate composed of polyimide resin, polyethylene terephthalate resin or the like.

The cationic group is preferably one in which, to the whole amount of the amino group and so forth, 80 to 100 mol % has been formed by neutralization or quaternization.

Examples of the acid group-containing compound usable for neutralization of an amino group such as a tertiary amino group for the cationic group include acid group-containing compounds of acetic acid, formic acid, propionic acid, succinic acid, glutaric acid, tartaric acid, adipic acid and phosphoric acid. Of these, an organic acid having a boiling point of 300° C. or less is preferably used.

Examples of the quaternizing agent usable for quaternization of the amino group or the like for the cationic group include dimethyl sulfate, diethyl sulfate, methyl chloride and ethyl chloride.

In order to give the metal adhesion layer excellent adhesiveness, the cationic group-containing polyurethane having a weight average molecular weight of 5,000 to 100,000 is preferably used.

The cationic group-containing polyurethane can be produced by reaction of, for example, polyol containing cationic group-containing polyol, polyisocyanate and, as needed, an amino group-containing compound and/or a chain elongating agent.

In order to introduce the cationic group into the (cationic group-containing) polyurethane, the polyol contains the cationic group-containing polyol as a must, and another polyol(s) can be used in combination therewith as needed.

Examples of the cationic group-containing polyol include: amino group-containing polyols such as N-methyl-diethanolamine, N-ethyl-diethanolamine and triethanolamine; and ones formed by naturalization of these with the acid group-containing compound or quaternization thereof with the quaternizing agent.

The metal adhesion layer can be produced by applying or impregnating the metal adhesion layer-forming composition containing the above cationic group-containing polyurethane to or into the substrate and thereafter removing the solvent. As the method for applying or impregnating the metal adhesion layer-forming composition to or into the substrate, a publicly-known method can be used. Applicable examples thereof include a gravure method, a coating method, a screen method, a roller method, a rotary method, a spray method and an inkjet method.

Examples of the solvent used for the cationic group-containing polyurethane include water, an organic solvent miscible with water, and a mixture of these. Examples of the organic solvent miscible with water include: alcohols such as methanol, ethanol, n-propanol and isopropanol; ketones such as acetone and methyl-ethyl-ketone; polyalkylene glycols such as ethylene glycol, diethylene glycol and propylene glycol; alkyl ethers of polyalkylene glycols; and lactams such as N-methyl-2-pyrrolidone. Only water may be used, a mixture of water and an organic solvent miscible with water may be used, or only an organic solvent miscible with water may be used. In terms of safety and a load on the environment, only water or a mixture of water and an organic solvent miscible with water is preferable, and only water is particularly preferable.

The content of the solvent is, to the whole amount of the metal adhesion layer-forming composition containing the cationic group-containing polyurethane, preferably 50 to 90 percent by mass and far preferably 65 to 85 percent by mass.

The metal adhesion layer-forming composition containing the cationic group-containing polyurethane may contain an additive and so forth as needed. Usable examples of the additive include: a crosslinking agent; a variety of fillers such as inorganic particles; and a thermosetting resin dissoluble or dispersible in/with a solvent such as phenol resin, urea resin, melamine resin, polyester resin, polyamide resin and urethane resin. The content of the additive is not particularly limited as far as it does not reduce the effects of the present invention, but preferably 0.01 to 40 percent by mass to the whole amount of the solid content in the metal adhesion layer-forming composition.

(Aromatic Heterocyclic Compound Containing Nitrogen Atom Having Unshared Electron Pair Uninvolved in Aromaticity)

The metal adhesion layer of the present invention is formed using a curable composition, and the curable composition preferably contains an aromatic heterocyclic compound containing a nitrogen atom(s) having an unshared electron pair uninvolved in aromaticity as the nitrogen atom-containing compound.

This can improve adhesiveness to the conductive metal layer because, in forming the conductive metal layer to be adjacent to the metal adhesion layer, the metal atom(s), which is the main component of the conductive metal layer, and the nitrogen atom(s) having an unshared electron pair uninvolved in aromaticity, which is contained in the metal adhesion layer, interact with each other.

The curable composition is a composition containing a compound which is cured by curing treatment. Hence, at the stage where the curable composition is disposed on the substrate by a predetermined method, it is in the movable state.

As the curable composition, a thermosetting composition or a photo-curable composition is preferable because curing the curable composition by heating or light irradiation is easy and simple.

Further, the curable composition is preferably a polymerizable composition.

Examples of the polymerization include radical polymerization, cationic polymerization and anionic polymerization.

Examples of the method for the polymerization include heating, light irradiation, and both of these. The method can be appropriately selected according to the type of the curable composition to use and the target properties of the metal adhesion layer.

The polymerizable composition of the present invention is preferably one type of monomer having a vinyl group in terms of ready polymerization and ready organic synthesis.

It is also preferable that the polymerizable composition of the present invention be a copolymerizable composition composed of two types of monomer having a vinyl group. Even when the polymerizable composition is not one type of the monomer, polymerization proceeds similarly. Hence, the polymerizable composition being the copolymerizable composition is also preferable.

Further, the polymerizable composition of the present invention may be a copolymerizable composition of a monomer(s) having a vinyl group and a monomer(s) having a thiol group.

The copolymerizable composition of the monomer having a vinyl group and the monomer having a thiol group changes degree of the effects to bring by changing the content rate of the monomer having a vinyl group or the monomer having a thiol group, but it can be appropriately adjusted according to the desired purpose such as improvement of rinse durability or improvement of storability for a long period of time under high temperature and high humidity which is brought by the polymerizable composition being the copolymerizable composition.

Further, it is also preferable that the polymerizable composition of the present invention be a composition containing monomer(s) having two or more vinyl groups in a molecule in terms of higher certainty of polymerization.

It is also preferable that the uncured raw material (ingredient) solution of the metal adhesion layer of the present invention contain a radical polymerization initiator. The uncured raw material solution of the metal adhesion layer containing a radical polymerization initiator more readily initiates polymerization, and, for example, can form a metal adhesion layer having excellent rinse durability on the whole with little unevenness at a specific part(s) due to the polymerization. Thus, the above radical polymerization initiator and/or a publicly-known radical polymerization initiator can be used according to the desired purpose.

In the present invention, the “nitrogen atom(s) having an unshared electron pair uninvolved in aromaticity” is a nitrogen atom(s) having an unshared electron pair, wherein the unshared electron pair is not directly involved in aromaticity of an unsaturated cyclic compound as an essential component. That is, it is a nitrogen atom, the unshared electron pair of which is, on the chemical structural formula, not involved in the delocalized 7E electron system on the conjugated unsaturated cyclic structure (aromatic ring) as a must for occurrence of aromaticity.

The “nitrogen atom(s) having an unshared electron pair uninvolved in aromaticity” defined in the present invention is important for occurrence of strong interaction of the unshared electron pair with the metal atom, which is the main component of the conductive metal layer. This nitrogen atom is preferably a nitrogen atom in a nitrogen-containing aromatic ring in terms of stability and durability.

The strength of the interaction between the nitrogen atom and the metal atom can be estimated from the strength of nucleophilicity of the nitrogen atom. That is, the stronger the nucleophilicity of the nitrogen atom is, the stronger the coordination force thereof to the metal atom is and accordingly the stronger the interaction therebetween is.

Examples of the method for forming the metal adhesion layer using the curable composition containing the aromatic heterocyclic compound containing a nitrogen atom(s) having an unshared electron pair uninvolved in aromaticity include: wet processes such as application, inkjet method(s), coating and dipping; and dry processes such as vapor deposition (resistance heating, the EB method, etc.), sputtering and CVD. The organic solvent used in the wet processes is not particularly limited, but, in terms of high versatility and reduction in environmental load, preferably ethanol, n-propanol, 2-propanol, PGME (1-methoxy-2-propanol), methyl acetate, MEK (methyl-ethyl-ketone) or water.

The metal adhesion layer is formed by applying the raw material solution of the aromatic heterocyclic compound contained in the curable composition onto the substrate and successively heating the raw material solution on the substrate or irradiating the same with light. Hence, it is not preferable that unintended reaction occur before the curing stage, and hence it is preferable to use a wet process by which film forming can be carried out under the milder conditions than those of a dry process such as vapor deposition by which the raw material solution is heated at high temperature so as to be evaporated and form a film (i.e. film forming).

It is preferable that the metal adhesion layer be formed by any of the above methods in such a way as to be a dry thickness of 1 μm or less, preferably 10 to 100 nm.

Specific examples of the aromatic heterocyclic compound containing a nitrogen atom(s) having an unshared electron pair uninvolved in aromaticity (in the monomer state), which constitutes the curable composition contained in the metal adhesion layer, are shown below, but not limited thereto.

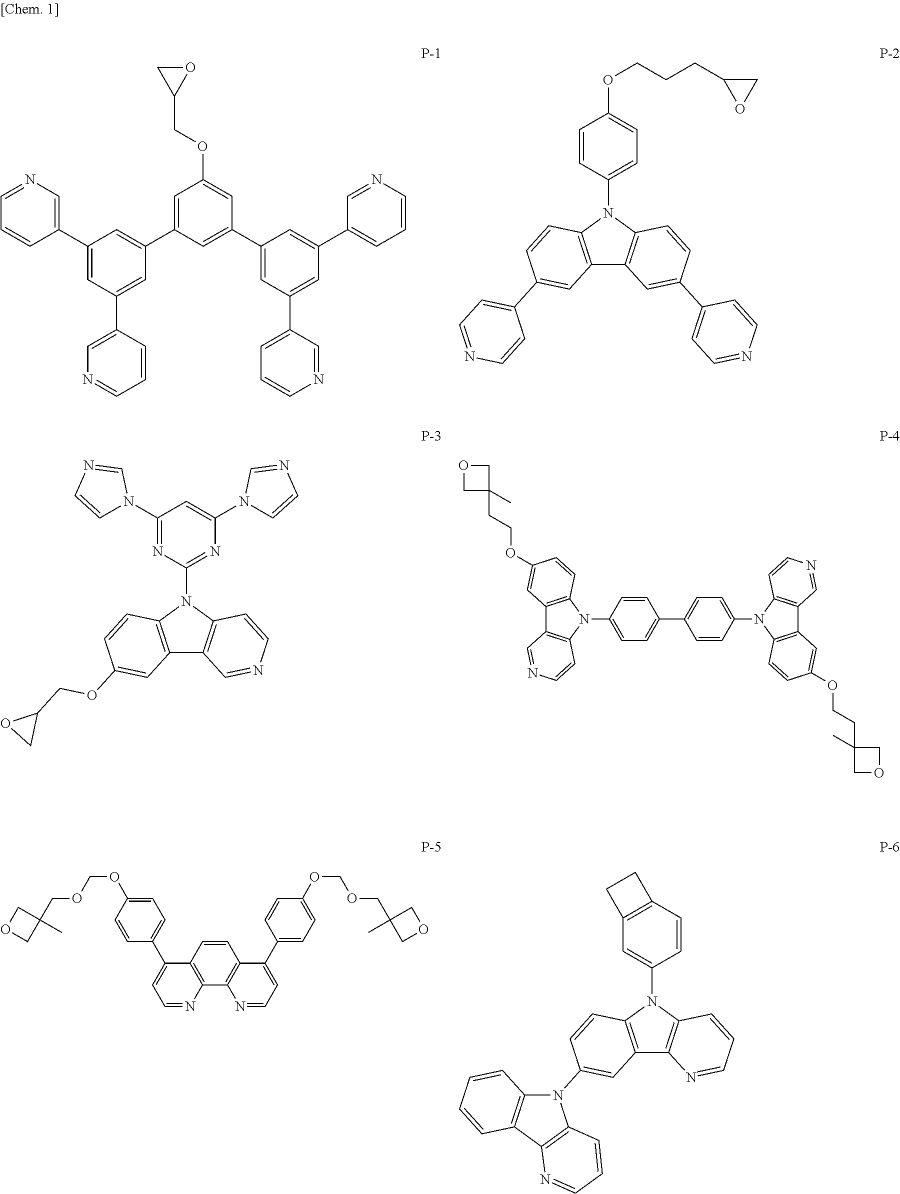 [SMILES: c1cncc(-c2cc(-c3cccnc3)cc(-c3cc(OCC4CO4)cc(-c4cc(-c5cccnc5)cc(-c5cccnc5)c4)c3)c2)c1 ; c1cc(-c2ccc3c(c2)c2cc(-c4ccncc4)ccc2n3-c2ccc(OCCCC3CO3)cc2)ccn1 ; c1cc2c(cn1)c1cc(OCC3CO3)ccc1n2-c1nc(-n2ccnc2)cc(-n2ccnc2)n1 ; CC1(CCOc2ccc3c(c2)c2cnccc2n3-c2ccc(-c3ccc(-n4c5ccncc5c5cc(OCCC6(C)COC6)ccc54)cc3)cc2)COC1 ; CC1(COCOc2ccc(-c3ccnc4c3ccc3c(-c5ccc(OCOCC6(C)COC6)cc5)ccnc34)cc2)COC1 ; c1ccc2c(c1)c1ncccc1n2-c1ccc2c(c1)c1ncccc1n2-c1ccc2c(c1)CC2]

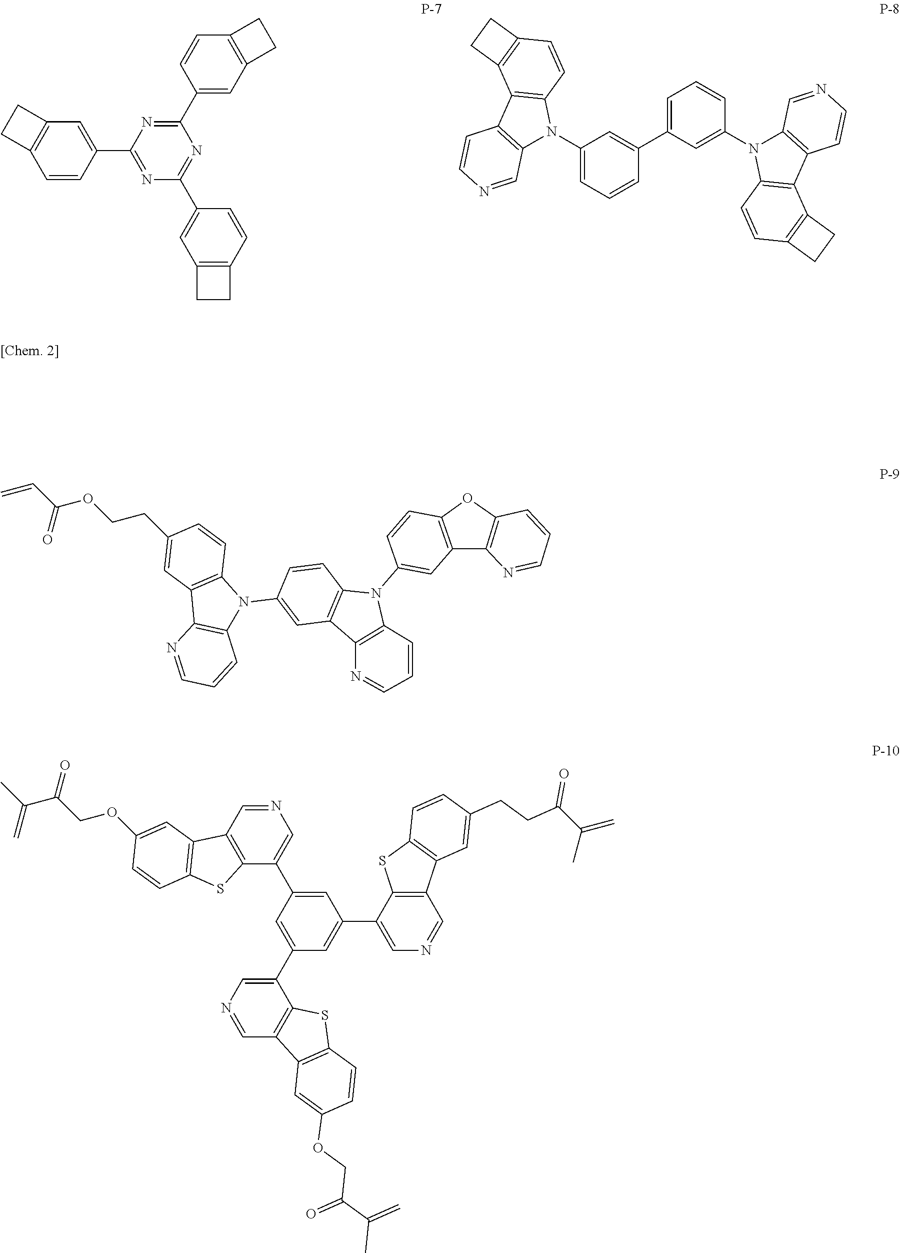 [SMILES: c1cc2c(cc1-c1nc(-c3ccc4c(c3)CC4)nc(-c3ccc4c(c3)CC4)n1)CC2 ; c1cc(-c2cccc(-n3c4cnccc4c4c5c(ccc43)CC5)c2)cc(-n2c3cnccc3c3c4c(ccc32)CC4)c1 ; C=CC(=O)OCCc1ccc2c(c1)c1ncccc1n2-c1ccc2c(c1)c1ncccc1n2-c1ccc2oc3cccnc3c2c1 ; C=C(C)C(=O)CCc1ccc2sc3c(-c4cc(-c5cncc6c5sc5ccc(OCC(=O)C(=C)C)cc56)cc(-c5cncc6c5sc5ccc(OCC(=O)C(=C)C)cc56)c4)cncc3c2c1]

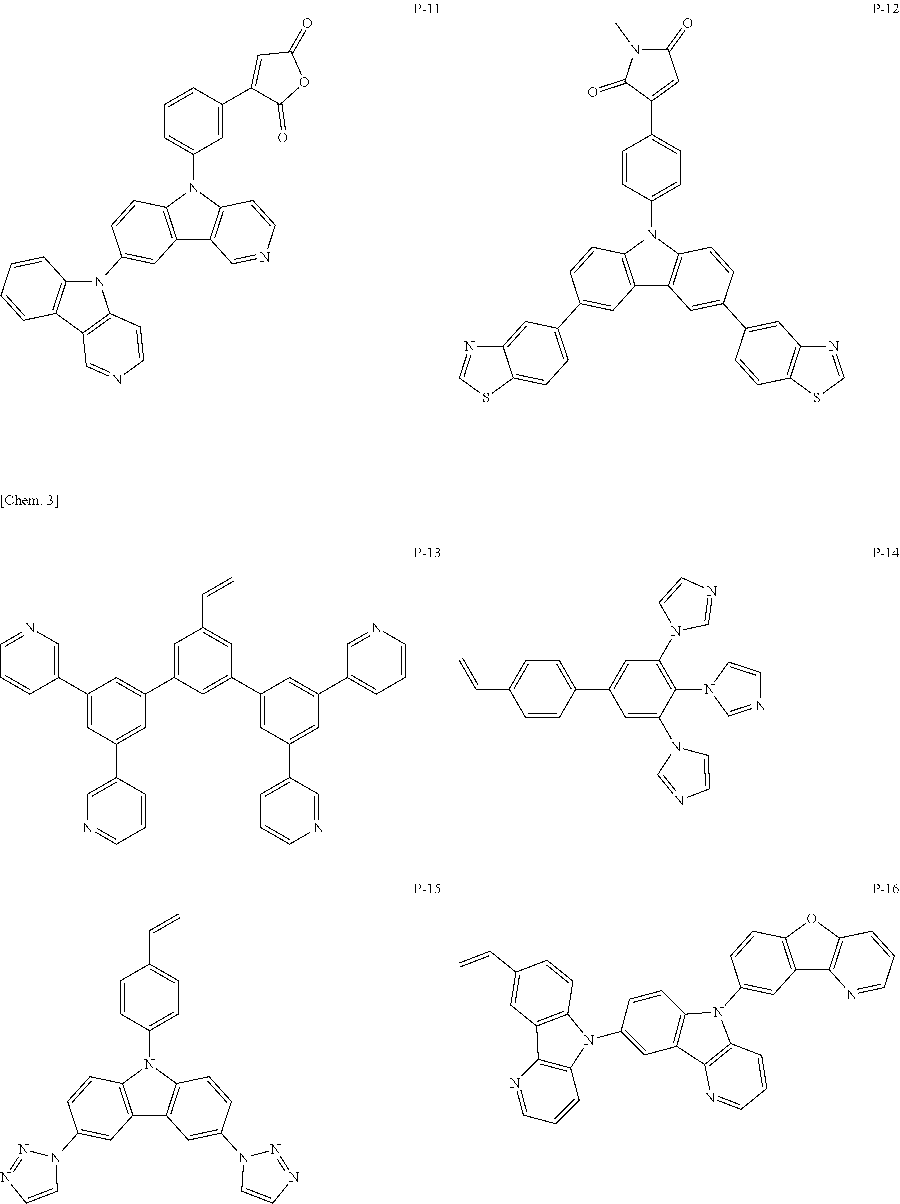 [SMILES: O=C1C=C(c2cccc(-n3c4ccncc4c4cc(-n5c6ccccc6c6cnccc65)ccc43)c2)C(=O)O1 ; CN1C(=O)C=C(c2ccc(-n3c4ccc(-c5ccc6scnc6c5)cc4c4cc(-c5ccc6scnc6c5)ccc43)cc2)C1=O ; C=Cc1cc(-c2cc(-c3cccnc3)cc(-c3cccnc3)c2)cc(-c2cc(-c3cccnc3)cc(-c3cccnc3)c2)c1 ; C=Cc1ccc(-c2cc(-n3ccnc3)c(-n3ccnc3)c(-n3ccnc3)c2)cc1 ; C=Cc1ccc(-n2c3ccc(-n4ccnn4)cc3c3cc(-n4ccnn4)ccc32)cc1 ; C=Cc1ccc2c(c1)c1ncccc1n2-c1ccc2c(c1)c1ncccc1n2-c1ccc2oc3cccnc3c2c1]

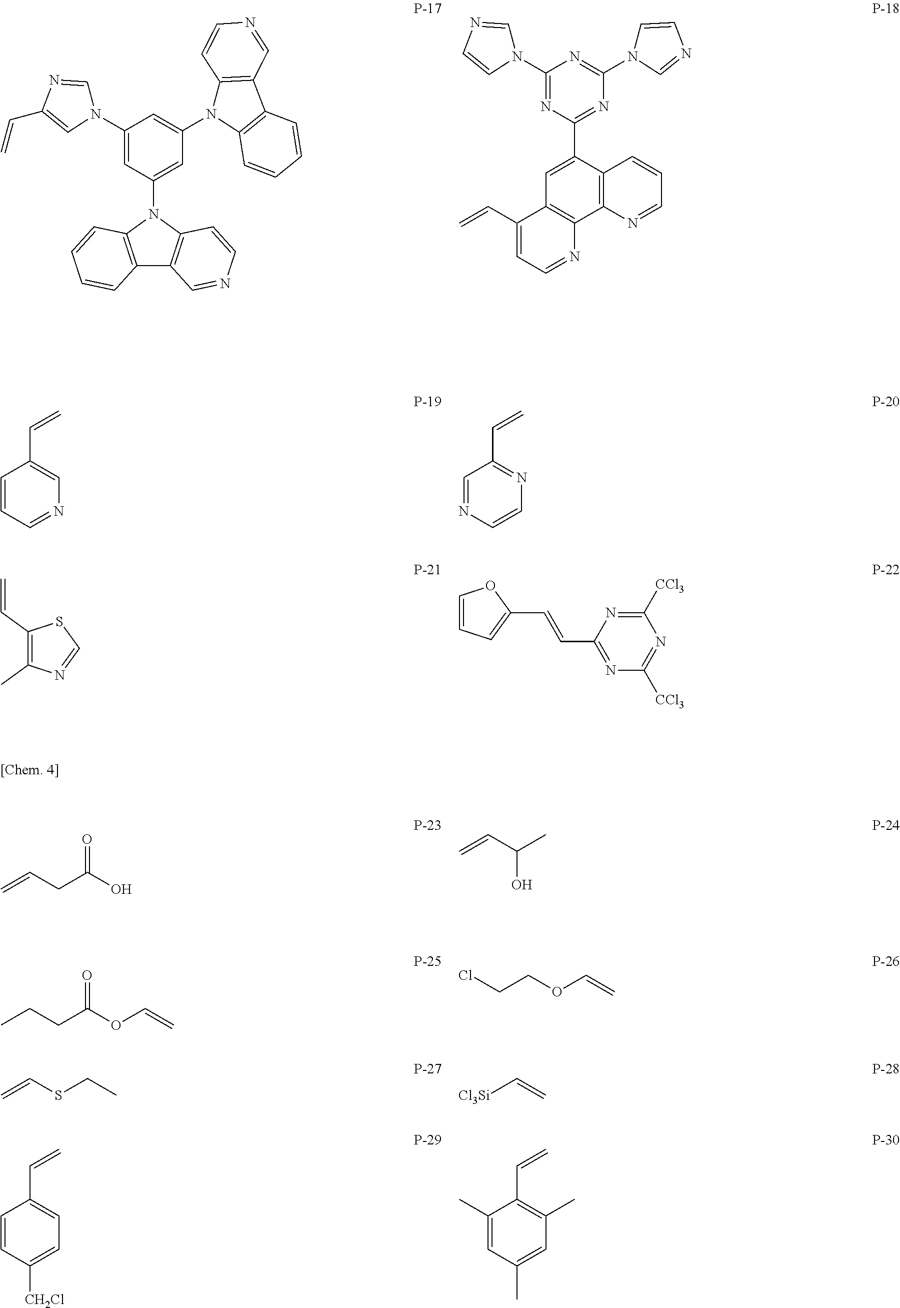

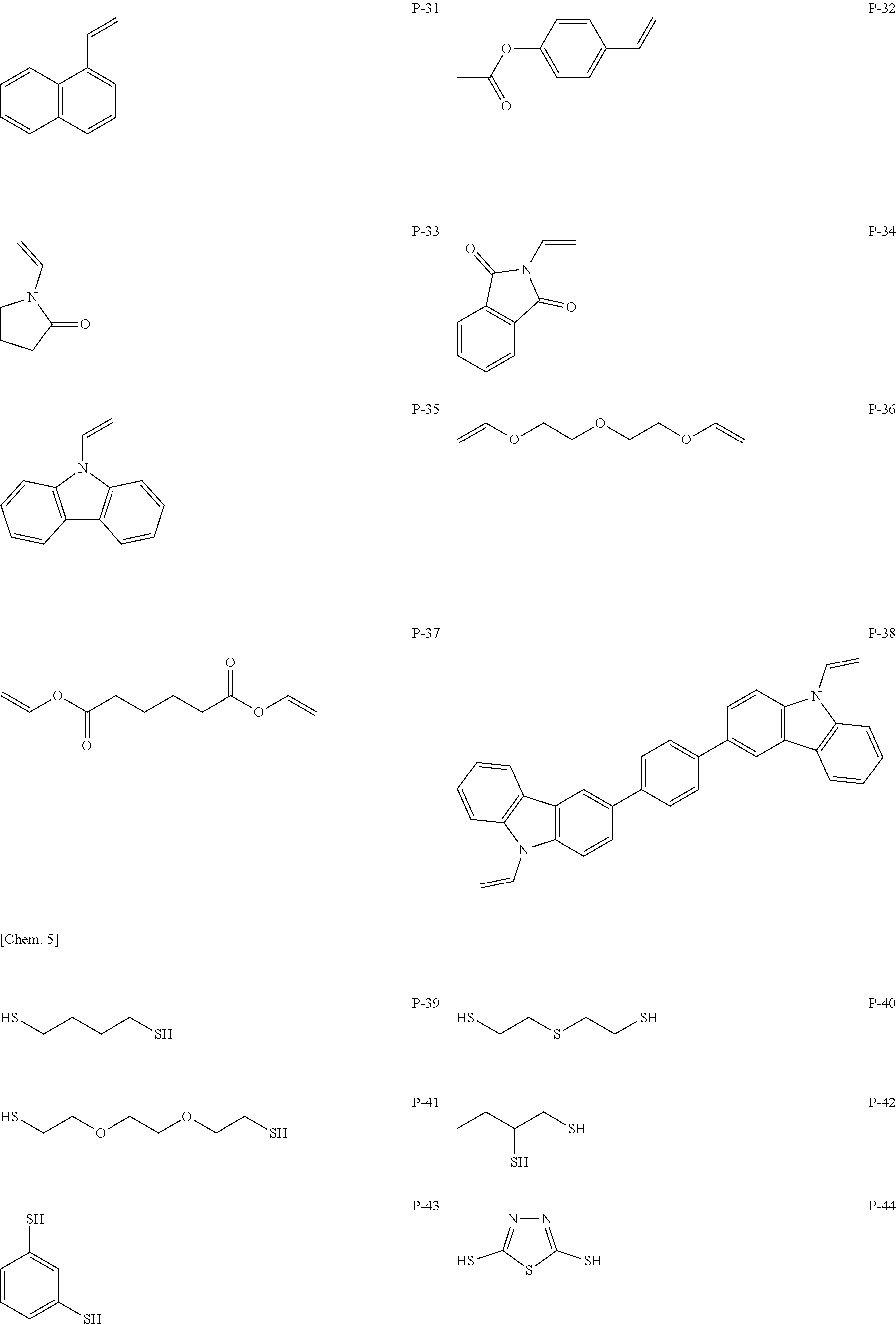

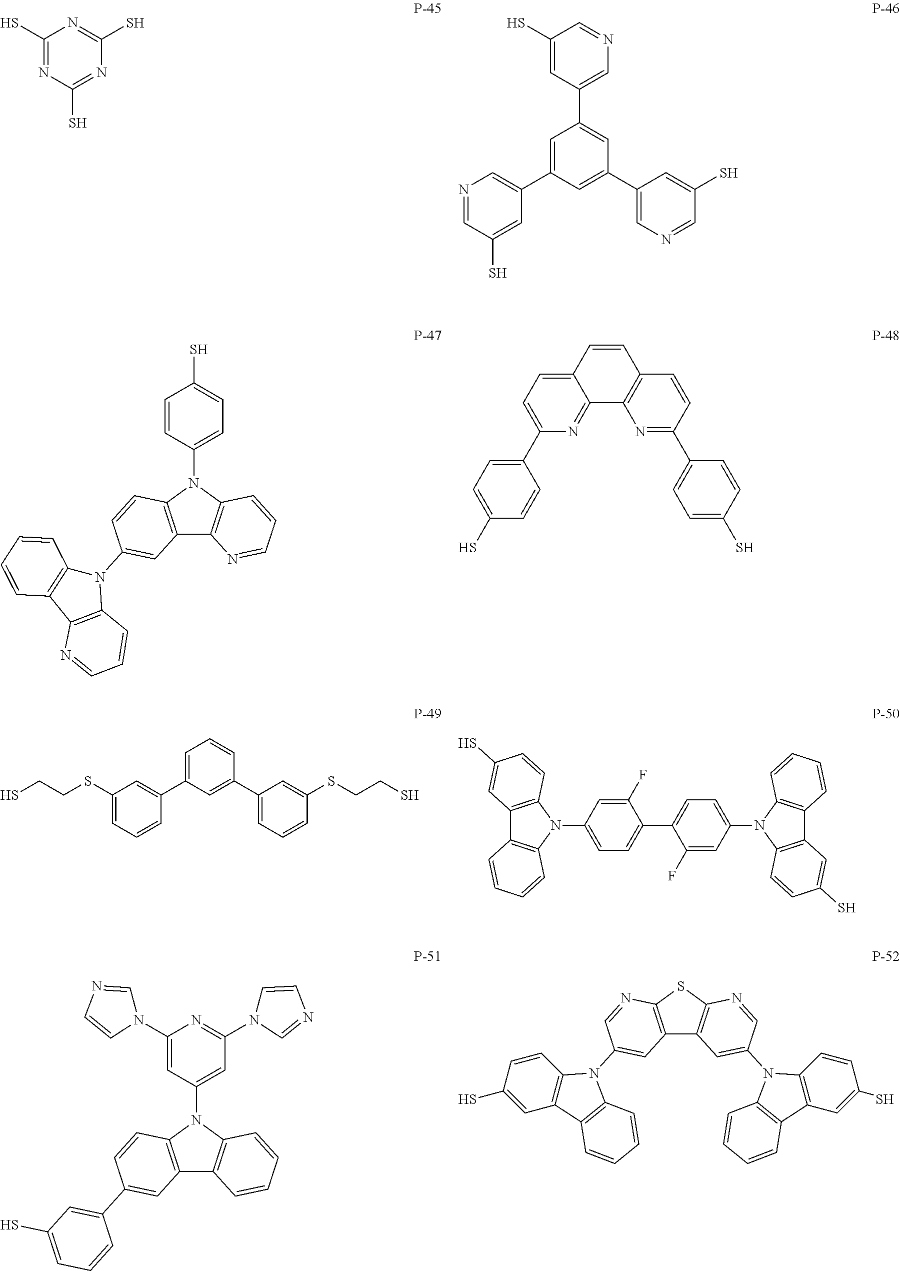

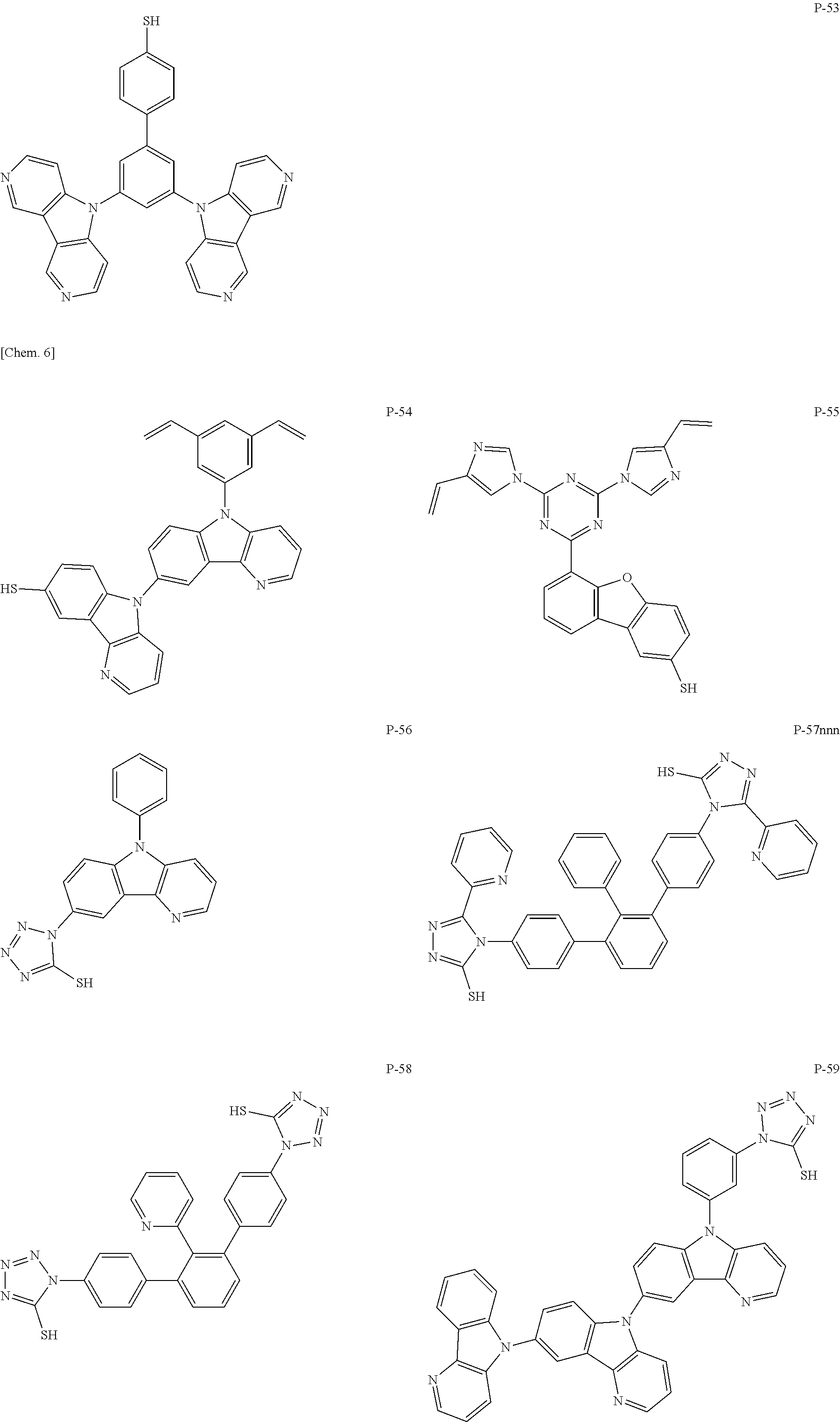

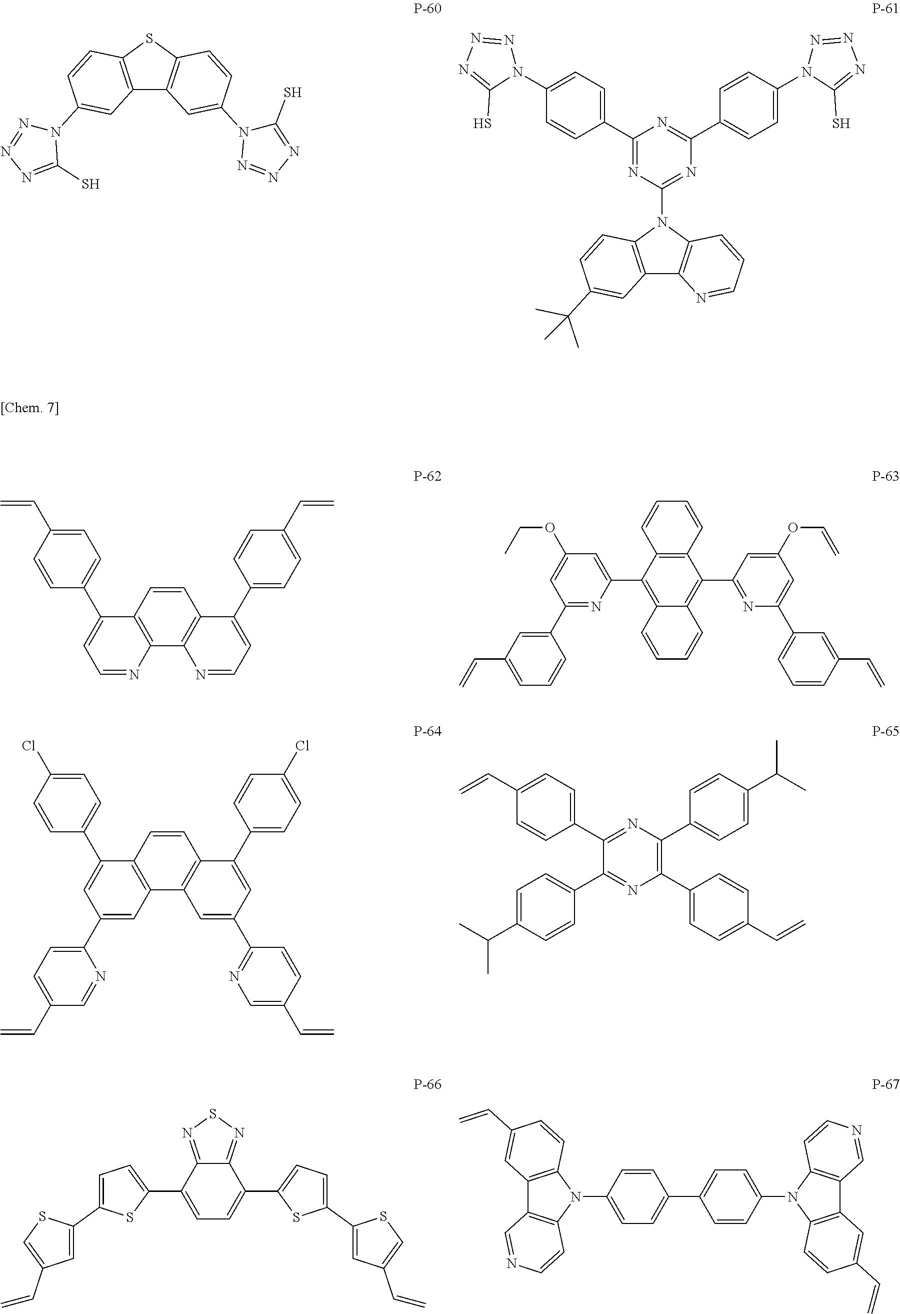

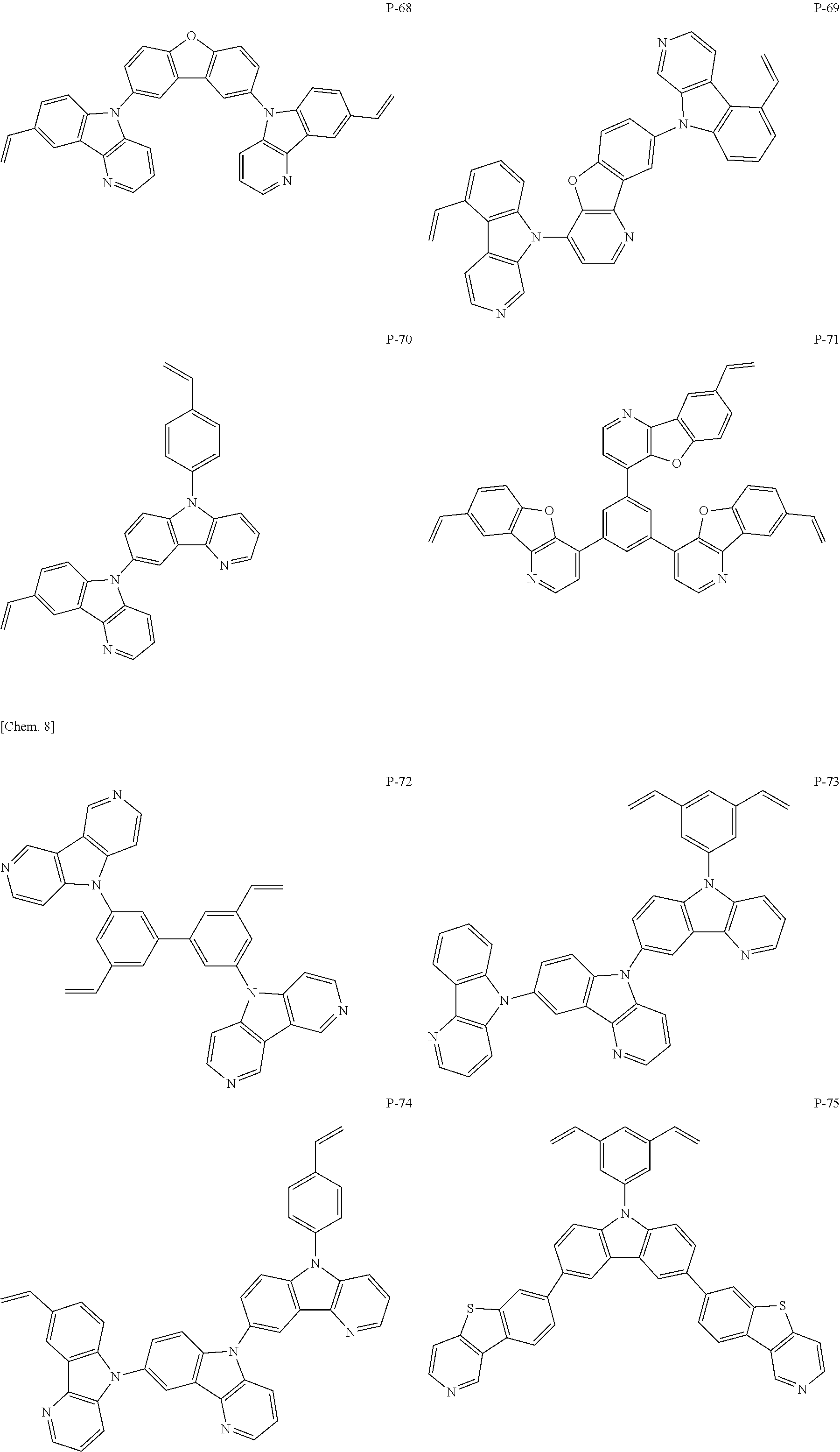

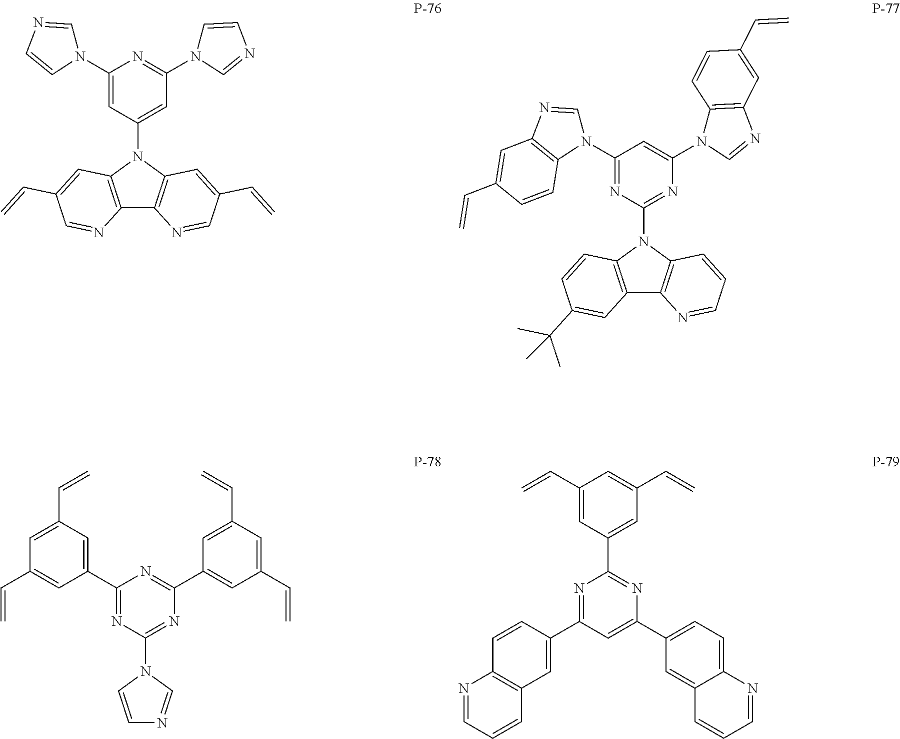 [SMILES: C=Cc1cnc2c3ncc(C=C)cc3n(-c3cc(-n4ccnc4)nc(-n4ccnc4)c3)c2c1 ; C=Cc1ccc2c(c1)ncn2-c1cc(-n2cnc3cc(C=C)ccc32)nc(-n2c3ccc(C(C)(C)C)cc3c3ncccc32)n1 ; C=Cc1cc(C=C)cc(-c2nc(-c3cc(C=C)cc(C=C)c3)nc(-n3ccnc3)n2)c1 ; C=Cc1cc(C=C)cc(-c2nc(-c3ccc4ncccc4c3)cc(-c3ccc4ncccc4c3)n2)c1]

(Vinyl Polymer)

The metal adhesion layer of the present invention preferably contains a vinyl polymer. As the vinyl polymer, used is a vinyl polymer obtained by polymerization of a vinyl monomer mixture containing: at their respective specific amounts described below, alkyl (meth)acrylate (a1) composed of one or more types selected from a group of methyl (meth)acrylate and ethyl (meth)acrylate; and alkyl (meth)acrylate (a2) containing an aliphatic or alicyclic alkyl group having 3 to 8 carbon atoms.

As the vinyl polymer contained in the metal adhesion layer, used is a vinyl polymer obtained by polymerization of the vinyl monomer mixture containing, to the whole amount of the vinyl monomer mixture, 10 to 70 percent by mass of the alkyl (meth)acrylate (a1) and 10 to 70 percent by mass of the alkyl (meth)acrylate (a2).

As the alkyl (meth)acrylate (a1), one of methyl (meth)acrylate and ethyl (meth)acrylate is used alone, or both of methyl (meth)acrylate and ethyl (meth)acrylate are used in combination. Of these, it is preferable to use methyl (meth)acrylate as a must, far preferable to use methyl methacrylate as a must, and particularly preferable to use methyl methacrylate alone in order to improve adhesiveness of the substrate and the metal adhesion layer and adhesiveness of the metal adhesion layer and the conductive metal layer.

The content of the alkyl (meth)acrylate (a1) being 10 to 70 percent by mass can sufficiently improve adhesiveness of the substrate and the metal adhesion layer and adhesiveness of the metal adhesion layer and the conductive metal layer.

The content of the alkyl (meth)acrylate (a1) is, to the whole amount of the vinyl monomer mixture, preferably 20 to 65 percent by mass and far preferably 35 to 65 percent by mass.

As the alkyl (meth)acrylate (a2), usable is one obtained, for example, by esterification of (meth)acrylic acid and mono-alcohol having an aliphatic or alicyclic alkyl group having 3 to 8 carbon atoms. Examples thereof include butyl (meth)acrylate such as n-butyl (meth)acrylate, i-butyl (meth)acrylate and t-butyl (meth)acrylate, 2-ethylhexyl (meth)acrylate, hexyl (meth)acrylate, cyclohexyl (meth)acrylate and octyl (meth)acrylate. Of these, it is preferable to use butyl (meth)acrylate, 2-ethylhexyl (meth)acrylate or cyclohexyl (meth)acrylate in terms of adhesiveness of the substrate and the metal adhesion layer and adhesiveness of the metal adhesion layer and the conductive metal layer, and far preferable to use butyl (meth)acrylate.

The content of the alkyl (meth)acrylate (a2) being 10 to 70 percent by mass can sufficiently improve adhesiveness of the substrate and the metal adhesion layer and adhesiveness of the metal adhesion layer and the conductive metal layer.

The content of the alkyl (meth)acrylate (a2) is, to the whole amount of the vinyl monomer mixture, preferably 20 to 65 percent by mass and far preferably 40 to 65 percent by mass.

It is preferable that the alkyl (meth)acrylate (a2) contain, to the whole amount of itself, 50 to 100 percent by mass of butyl (meth)acrylate.

The vinyl polymer is preferably a vinyl polymer obtained by polymerization of a vinyl monomer mixture containing, in addition to the alkyl (meth)acrylate (a1) and the alkyl (meth)acrylate (a2), a carboxy group-containing vinyl monomer (a3), which contains a carboxy group. This is preferable because it can form a metal adhesion layer having, in addition to the above effects, followability, such as adhesiveness or flexibility, of a level to be able to follow deformation or the like of the substrate without separating therefrom even when a manufactured transparent electrode is bent or curved.

Examples of the carboxy group-containing vinyl monomer (a3) include: a vinyl monomer having two or more carboxy groups such as fumaric acid and maleic acid itaconic acid; and a vinyl monomer having one carboxy group (a3-1) such as (meth)acrylic acid. Of these, a vinyl monomer having one carboxy group (a3-1) is preferable for very excellent adhesiveness to the substrate composed of resin, such as polyimide resin or polyethylene terephthalate, which is generally poor in adhesiveness.

Examples of the vinyl monomer having one carboxy group (a3-1) include (meth)acrylic acid, β-carboxyethyl acrylate, 2-(meth)acryloylpropionic acid, crotonic acid, itaconic acid-half ester, maleic acid-half ester, and β-(meth)acryloyloxyethyl hydrogen succinate, and also commercially-available products such as ARONIX M-5300 (ω-carboxy-polycaprolactone monoacrylate manufactured by TOAGOSEI CO., LTD.).

The content of the vinyl monomer having one carboxy group (a3-1) is, to the whole amount of the vinyl monomer mixture, which is used in producing the vinyl polymer, preferably 1 to 20 percent by mass and far preferably 1 to 10 percent by mass in order to form the metal adhesion layer which can follow deformation or the like of the substrate without separating from the substrate even if strong force, for example, by bending or curving is applied thereto.

The vinyl monomer mixture used in producing the vinyl polymer may appropriately contain, in addition to the alkyl (meth)acrylate (a1), the alkyl (meth)acrylate (a2) and the carboxy group-containing vinyl monomer (a3), another vinyl monomer(s) can be used in combination therewith as needed.

The metal adhesion layer can be produced by applying or impregnating the metal adhesion layer-forming composition containing the above vinyl polymer to or into the substrate and thereafter removing the solvent. As the method for applying or impregnating the metal adhesion layer-forming composition to or into the substrate, a publicly-known method can be used. Applicable examples thereof include a gravure method, a coating method, a screen method, a roller method, a rotary method, a spray method and an inkjet method.

Examples of the solvent used for the vinyl polymer include solvents such as ethyl acetate and methyl-ethyl-ketone. Of these, ethyl acetate, methyl-ethyl-ketone or toluene is preferably used because they can easily adjust the weight average molecular weight to a preferable range.

The content of the solvent is, to the whole amount of the metal adhesion layer-forming composition containing the vinyl polymer, preferably 30 to 90 percent by mass. Meanwhile, the content of the vinyl polymer is, to the whole amount of the metal adhesion layer-forming composition, preferably 10 to 70 percent by mass.

The metal adhesion layer-forming composition containing the vinyl polymer may contain an additive and so forth as needed. Usable examples of the additive include: a crosslinking agent; a variety of fillers such as inorganic particles; and a thermosetting resin dissoluble or dispersible in/with a solvent such as phenol resin, urea resin, melamine resin, polyester resin, polyamide resin and urethane resin. The content of the additive is not particularly limited as far as it does not reduce the effects of the present invention, but preferably 0.01 to 40 percent by mass to the whole amount of the solid content in the metal adhesion layer-forming composition.

(Coupling Agent)

The metal adhesion layer of the present invention preferably contains a coupling agent.

Examples of the coupling agent contained in the metal adhesion layer include a silane coupling agent, a titanium coupling agent, a zirconium coupling agent and an aluminum coupling agent.

The coupling agent contained in the metal adhesion layer of the present invention is preferably a silane coupling agent expressed by the following general formula [i] or a compound expressed by the general formula [ii], the compound being obtained by hydrolysis of the silane coupling agent.

X—R—Si—Y₃ General Formula [i]:

X—R—Si(OH)₃ General Formula [ii]:

In the above general formulae [i] and [ii], X represents a group having a nitrogen atom, R represents a C1-C6 alkylene group, i.e. having 1 to 6 carbon atoms, which links X with a silicon atom, and Y represents a C1-C3 alkoxy group, i.e. having 1 to 3 carbon atoms, having hydrolyzability which links with the silicon atom.

In the general formulae [i] and [ii], X represents a group having a nitrogen atom, and the group having a nitrogen atom has an affinity for the metal atom contained in the conductive metal layer, and therefore can significantly improve fixing property of the metal adhesion layer and the conductive metal layer to one another. Although the reason for appearance of this affinity remains to be clarified, it is conjectured that occurrence of coordinate bond between the nitrogen atom in X and the metal atom is one factor. As the X, a group having a primary amine structure (—NH₂), a secondary amine structure (—NH—) or a tertiary amine structure (—N═) is usable, but preferably an amino group having a structure (—NH₂) in which a nitrogen atom is present near the terminal of X.

In the general formulae [i] and [ii], R is a C1-C6 alkylene group which links X with a silicon atom, and the number of carbon atoms is preferably two or three.

In the general formulae [i] and [ii], Y located to face X is a C1-C3 alkoxy group having hydrolyzability which links with the silicon atom.

Y or the OH group has dehydration condensation with the OH group present on the surface of the substrate by heat treatment which is carried out after a solution containing the silane coupling agent expressed by the general formula [i] or the compound expressed by the general formula [ii] is applied onto the substrate. This improves adhesiveness between the substrate and the metal adhesion layer.

If the silane coupling agent expressed by the general formula [i] or the compound expressed by the general formula [ii] is used, the metal adhesion layer can be formed on the substrate by applying the silane coupling agent expressed by the general formula [i] and the compound expressed by the general formula [ii] as an aqueous solution with 0.01 to 5 percent by mass thereof onto the substrate such that the solid content is 0.005 to 250 g/m² and then carrying out heat treatment. Although it depends on thermal stability of the silane coupling agent expressed by the general formula [i] and the compound expressed by the general formula [ii], the conditions for the heat treatment are preferably about 100° C. to 150° C. and about 0.5 to 2 hours.

(Metal Oxide)

The metal adhesion layer of the present invention preferably contains a metal oxide. The metal oxide contained in the metal adhesion layer of the present invention is preferably one type or two or more types of metal oxide selected from a group of Ag, Cu, Sn, Pd, Zn, Ni, Mo, Cr, Mn, Al, Zr, Ti, Ru, Pt, In and Si. Specific examples thereof include Ag₂O, CuO, PdO, ZnO, NiO, MoO₂, Cr₂O₃, MnO₂, Al₂O₃, ZrO, TiO₂, In₂O₃ and SiO₂.

Further, it is preferable to contain, in addition to the metal oxide, one type or two or more types of resin. Examples of the resin include acrylic, vinyl acetate, epoxy, polyester, polyurethane, cellulose and polyvinylpyrrolidone, modified resins of these, and copolymers containing these as structural units. The resin contains preferably one type or two or more types of component selected from a group of an isocyanate component, a polyester component and a polyether component as a constitutive component(s), and particularly preferably these three components as constitutive components. Examples of the isocyanate component, the polyester component and the polyether component include 2,4-tolylenediisocyanate, polycaprolactone and polyethylene glycol, respectively. A specific example is a copolymer containing 2,4-tolylenediisocyanate, polycaprolactone and polyethylene glycol as constitutive components at a mole ratio of 20:50:1.

Further, it is preferable to contain, in addition to the metal oxide, one type or two or more types of alkoxide. Examples of the metal alkoxide include tetraethoxysilane, tetrabutoxytitanium, titanium isopropoxide and zirconium butoxide.

Further, it is preferable to contain, in addition to the metal oxide, one type or two or more types of metal soap. Examples of the metal soap include calcium stearate, magnesium stearate, zinc stearate and 2-ethylhexanoic acid tin.

Further, it is preferable to contain, in addition to the metal oxide, one type or two or more types of coupling agent. Examples of the coupling agent include 3-mercaptopropylmethyldimethoxysilane and triethanolamine titanate.

If the metal oxide is used, particularly preferable examples of the method for forming the metal adhesion layer include spray coating, dispenser coating, spin coating, knife coating, slit coating, inkjet coating, screen printing, offset printing and die coating, but are not limited thereto, and hence any method can be used. The applied substance applied on the substrate is kept at 20° C. to 100° C. for 10 seconds to 30 minutes to be dried or kept for 10 seconds to 30 minutes with air of 20° C. to 100° C. being sent thereto to be dried, preferably kept for 15 seconds with air of 40° C. being sent thereto to be dried.

(Mercapto Group-Containing Compound)

When the metal adhesion layer of the present invention contains the metal oxide, it is preferable that the metal adhesion layer further contain a mercapto group-containing compound.

The mercapto group-containing compound is represented by R—SH, wherein R represents, for example, an alkyl group, a cycloalkyl group, an alkenyl group, an alkynyl group, an aromatic hydrocarbon group, an aromatic heterocyclic group, a heterocyclic group, an alkoxy group, a cycloalkoxy group, an aryloxy group or the like.

Examples of the mercapto group-containing compound include 2-mercaptotriazole.

[Transparent Conductive Layer]

The transparent conductive layer is formed on the substrate in such a way as to cover the metal adhesion layer, the thin metal wires and the plating layer. The transparent conductive layer is formed to cover unevenness of the conductive metal layer so as to make the surface smooth or flat.

The transparent conductive layer contains at least a material having conductivity (conductive material). Examples of the conductive material include a transparent conductive material, a conductive polymer and carbon nanotube(s). The “conductive” of the transparent conductive layer and the conductive material means a state in which electricity flows and means that sheet resistance measured by a method in conformity with JIS K 7194-1994, “Testing Method for Resistivity of Conductive Plastics with a Four-Point Probe Array”, is less than 10×7 Ω/sq.

The electric resistance of the transparent conductive layer is, in surface resistivity, preferably 10,000 Ω/sq. or less and far preferably 2,000 Ω/sq. or less.

The dry thickness of the transparent conductive layer is preferably 30 to 2,000 nm. The dry thickness thereof is far preferably 1,000 nm or less in terms of transparency while far preferably 100 nm or more in terms of conductivity and still far preferably 200 nm or more in terms of surface smoothness of an electrode.

The transparent conductive material is preferably a transparent conductive metal oxide. Examples thereof include: conductive oxides such as indium tin oxide (ITO), zinc oxide (ZnO), tin oxide (SnO₂) and IGZO; and amorphous transparent conductive films of indium zinc oxide (IZO), IDIXO (In₂O₃—ZnO) and so forth.

If the transparent conductive layer is formed of a conductive polymer, it is preferable to contain both a conductive polymer and a nonconductive polymer. The transparent conductive layer containing: a conductive polymer; and a nonconductive polymer containing a self-dispersing polymer and/or a hydroxy group-containing polymer can reduce a necessary amount of the conductive polymer without reducing conductivity of the transparent conductive layer. Consequently, a transparent electrode having both high conductivity and high transparency can be obtained.

(Conductive Polymer)

The conductive polymer contains a π-conjugated conductive polymer and a polyanion. The conductive polymer can be easily produced by subjecting the below-described precursor monomer(s) for forming the π-conjugated conductive polymer to chemical oxidative polymerization under the presence of an appropriate oxidizer, an appropriate oxidation catalyst and the polyanion described below.

(π-Conjugated Conductive Polymer)

The π-conjugated conductive polymer is not particularly limited, and usable examples thereof include chain conductive polymers such as polythiophenes (including simple polythiophene, the same applies to the following), polypyrrols, polyindoles, polycarbazoles, polyanilines, polyacetylenes, polyfurans, polyparaphenylene vinylenes, polyazulenes, polyparaphenylenes, polyparaphenylene sulfides, polyisothianaphthenes and polythiazyls. Of these, in terms of conductivity, transparency, stability and so forth, polythiophenes and polyanilines are preferable, and polyethylene dioxythiophene is the most preferable.

(Precursor Monomer for π-Conjugated Conductive Polymer)

The precursor monomer used for forming the π-conjugated conductive polymer has a n-conjugated system in the molecule, and when the precursor monomer is polymerized by the action of an appropriate oxidizer too, the π-conjugated system is formed in the principal chain. Examples thereof include pyrroles and derivatives thereof, thiophenes and derivatives thereof, and anilines and derivatives thereof.

Specific examples of the precursor monomer include pyrrole, 3-methylpyrrole, 3-ethylpyrrole, 3-n-propylpyrrole, 3-butylpyrrole, 3-octylpyrrole, 3-decylpyrrole, 3-dodecylpyrrole, 3,4-dimethylpyrrole, 3,4-dibutylpyrrole, 3-carboxylpyrrole, 3-methyl-4-carboxylpyrrole, 3-methyl-4-carboxyethylpyrrole, 3-methyl-4-carboxybutylpyrrole, 3-hydroxypyrrole, 3-methoxypyrrole, 3-ethoxypyrrole, 3-butoxypyrrole, 3-hexyloxypyrrole, 3-methyl-4-hexyloxypyrrole, thiophene, 3-methylthiophene, 3-ethylthiophene, 3-propylthiophene, 3-butylthiophene, 3-hexylthiophene, 3-heptylthiophene, 3-octylthiophene, 3-dechylthiophene, 3-dodecylthiophene, 3-octadecylthiophene, 3-bromothiophene, 3-chlorothiophene, 3-iodothiophene, 3-cyanothiophene, 3-phenylthiophene, 3,4-dimethylthiophene, 3,4-dibutylthiophene, 3-hydroxythiophene, 3-methoxythiophene, 3-ethoxythiophene, 3-butoxythiophene, 3-hexyloxythiophene, 3-heptyloxythiophene, 3-octyloxythiophene, 3-decyloxythiophene, 3-dodecyloxythiophene, 3-octadecyloxythiophene, 3,4-dihydroxythiophene, 3,4-dimethoxythiophene, 3,4-diethoxythiophene, 3,4-dipropoxythiophene, 3,4-dibutoxythiophene, 3,4-dihexyloxythiophene, 3,4-diheptyloxythiophene, 3,4-dioctyloxythiophene, 3,4-didecyloxythiophene, 3,4-didodecyloxythiophene, 3,4-ethylene dioxythiophene, 3,4-propylene dioxythiophene, 3,4-butene dioxythiophene, 3-methyl-4-methoxythiophene, 3-methyl-4-ethoxythiophene, 3-carboxythiophene, 3-methyl-4-carboxythiophene, 3-methyl-4-carboxyethylthiophene, 3-methyl-4-carboxybutylthiophene, aniline, 2-methylaniline, 3-isobutylaniline, 2-aniline sulfonic acid and 3-aniline sulfonic acid.

(Polyanion)

The polyanion used for the conductive polymer is exemplified by: substituted or non-substituted polyalkylene; substituted or non-substituted polyalkenylene; substituted or non-substituted polyimide; substituted or non-substituted polyamide; substituted or non-substituted polyester; and copolymers thereof, and is composed of a structural unit having an anionic group and a structural unit having no anionic group.

The polyanion is a polymer to dissolve or disperse the π-conjugated conductive polymer in a solvent. The anionic group of the polyanion functions as a dopant for the π-conjugated conductive polymer and improves conductivity and heat resistance of the π-conjugated conductive polymer.

The anionic group of the polyanion is any functional group with which the π-conjugated conductive polymer can be doped by chemical oxidation. In particular, a monosubstituted sulfuric acid ester group, a monosubstituted phosphoric acid ester group, a phosphoric acid group, a carboxy group, a sulfo group and so forth are preferable in terms of easiness in producing and stability. In terms of the doping effect of the functional group on the π-conjugated conductive polymer, a sulfo group, a monosubstituted sulfuric acid ester group and a carboxy group are far preferable.

Specific examples of the polyanion include polyvinylsulfonic acid, polystyrenesulfonic acid, polyallylsulfonic acid, polyacrylic acid ethylsulfonic acid, polyacrylic acid butylsulfonic acid, poly-2-acrylamide-2-methylpropanesulfonic acid, polyisoprenesulfonic acid, polyvinylcarboxylic acid, polystyrenecarboxylic acid, polyallylcarboxylic acid, polyacrylcarboxylic acid, polymethacrylcarboxylic acid, poly-2-acrylamide-2-methylpropanecarboxylic acid, polyisoprenecarboxylic acid and polyacrylic acid. The polyanion may be a homopolymer of any of these or a copolymer composed of two or more types of these.

The polyanion may further contain fluorine atom in the compound. Specific examples thereof include Nafion (manufactured by DuPont K.K.) containing a perfluorosulfonic acid group and Flemion (manufactured by Asahi Glass Co., Ltd.) composed of perfluorovinyl ether containing a carboxylic acid group. These fluorinated polyanions can each form a transparent electrode provided with a positive hole injection function by being used in combination with a non-fluorinated polyanion, which is desired in terms of element efficiency and productivity.

Degree of polymerization of the polyanion is preferably in a range from 10 to 100,000 in the number of monomer units and, in terms of dissolubility in a solvent and conductivity, far preferably in a range from 50 to 10,000 in the number of monomer units.

A method for producing the polyanion is exemplified by: a method of, using acid, direct introduction of an anionic group into a polymer having no anionic group; a method of, using a sulfonating agent, sulfonation of a polymer having no anionic group; and a method of polymerization of an anionic group-containing polymerizable monomer(s).

The method of polymerization of the anionic group-containing polymerizable monomer is exemplified by a method of subjecting, in a solvent, anionic group-containing polymerizable monomers to oxidative polymerization or radical polymerization under the presence of an oxidizer and/or a polymerization catalyst.

More specifically, a predetermined amount of anionic group-containing polymerizable monomers is dissolved into a solvent, the resulting product is kept at a constant temperature, and a solution in which a predetermined amount of an oxidizer and/or a polymerization catalyst is dissolved into a solvent in advance is added thereto and reacts therewith for a predetermined time. The polymer produced by the reaction is adjusted to be a certain concentration using a solvent. In this production method, the anionic group-containing polymerizable monomer may be copolymerized with a polymerizable monomer(s) containing no anionic group.

The oxidizer, oxidization catalyst and solvent used in polymerization of the anionic group-containing polymerizable monomer are the same as those used in polymerization of the precursor monomer for forming the π-conjugated conductive polymer.

If the produced polymer is polyanionic salt, it is preferable to denature polyanionic salt to polyanionic acid. A method for denaturing polyanionic salt to polyanionic acid is exemplified by: ion exchange using ion exchange resin; dialysis; and ultrafiltration. Of these, ultrafiltration is preferable in terms of easiness in work.

The ratio of the π-conjugated conductive polymer to the polyanion contained in the conductive polymer, namely, “π-conjugated conductive polymer”:“polyanion”, in mass ratio is preferably in a range from 1:1 to 1:20 and, in terms of conductivity and dispersibility, far preferably in a range from 1:2 to 1:10.

The oxidizer, which is used in subjecting the precursor monomer for forming the π-conjugated conductive polymer to chemical oxidative polymerization under the presence of the polyanion so as to produce the conductive polymer, is any of oxidizers which are suitable for oxidative polymerization of pyrrole and mentioned in J. Am. Chem. Soc., Vol. 85, p. 454 (1963), for example.

For practical reasons, it is preferable to use an inexpensive and easily handleable oxidizer, and examples thereof include: iron (III) salts such as FeCl₃, Fe(ClO₄)₃, and iron (III) salt of organic acid or inorganic acid containing organic residue; hydrogen peroxide; potassium dichromate; alkali persulfate (potassium persulfate, sodium persulfate, etc.); ammonium; alkali perborate; potassium permanganate; and copper salt such as copper tetrafluoroborate.

In addition, air and oxygen under the presence of a catalytic amount of metal ion such as iron ion, cobalt ion, nickel ion, molybdenum ion or vanadium ion can be used as the oxidizer as needed. Using persulfate or iron (III) salt of organic acid or inorganic acid containing organic residue has a great practical advantage because of its non-corrosiveness.

Examples of the iron (III) salt of inorganic acid containing organic residue include iron (III) salts, namely, Fe (III) salts, of: alkanol sulfuric acid half-ester having 1 to 20 carbon atoms such as lauryl sulfate; alkylsulfonic acid having 1 to 20 carbon atoms such as methane sulfonic acid or dodecane sulfonic acid; aliphatic carboxylic acid having 1 to 20 carbon atoms such as 2-ethylhexylcarboxylic acid; aliphatic perfluorocarboxylic acid such as trifluoroacetic acid or perfluorooctanoic acid; aliphatic dicarboxylic acid such as oxalic acid; and optionally-alkyl-substituted aromatic sulfonic acid having 1 to 20 carbon atoms such as benzenesulfonic acid; p-toluenesulfonic acid; and dodecylbenzene sulfonic acid.

For this sort of conductive polymer, a commercially-available material can also be preferably used.

For example, a conductive polymer (abbreviated as PEDOT/PSS) composed of poly(3,4-ethylene dioxythiophene) and polystyrenesulfonic acid is commercially available from Heraeus as Clevios Series, from Aldrich as PEDOT-PSS 483095 and 560596, and from Nagase ChemteX Corporation as Denatron Series. In addition, polyaniline is commercially available from Nissan Chemical Industries, Ltd. as ORMECON Series.

(Nonconductive Polymer)

Examples of the nonconductive polymer include a self-dispersing nonconductive polymer and a hydroxy group-containing polymer.

(Self-Dispersing Nonconductive Polymer)

The self-dispersing nonconductive polymer is a self-dispersing polymer being dispersible in an aqueous solvent, containing a dissociable group and having a glass transition temperature of 25° C. to 150° C. The dissociable group-containing self-dispersing polymer dispersible in an aqueous solvent does not contain a surfactant, an emulsifier and so forth which assist micelle formation, but is dispersible by itself in an aqueous solvent. The “dispersible in an aqueous solvent” means that colloidal particles composed of binder resin are dispersed in an aqueous solvent without being aggregated.

The used amount of the dissociable group-containing self-dispersing polymer is, to the conductive polymer, preferably 50 to 1,000 percent by mass, far preferably 100 to 900 percent by mass and still far preferably 200 to 800 percent by mass.

The size of colloidal particles is around 0.001 to 1 μm (1 to 1,000 nm) in general. The size of colloidal particles is preferably 3 to 500 nm, far preferably 5 to 300 nm and still far preferably 10 to 200 nm. With respect to the above colloidal particles, measurement thereof can be carried out with a light scattering photometer.

The aqueous solvent includes not only pure water (distilled water and deionized water included) but also an aqueous solution containing acid, alkali, salt or the like; a water-containing organic solvent; and a hydrophilic organic solvent. Examples of the aqueous solvent include pure water (distilled water and deionized water included); alcoholic solvents such as methanol and ethanol; and a mixed solvent of water and alcohol.

pH of the dispersion of the dissociable group-containing self-dispersing polymer used for manufacturing a transparent electrode is desired to be in a range in which the dispersion does not separate from the conductive polymer solution, which is compatibilized with the dispersion later, preferably in a range from 0.1 to 11.0 and far preferably in a range from 3.0 to 9.0.

The dissociable group-containing self-dispersing polymer is preferably transparent. The dissociable group-containing self-dispersing polymer is not particularly limited as far as it is a medium which forms a film. It is not particularly limited as far as it does not bleed out to the transparent electrode surface and does not influence an organic functional layer(s) or the like when an electronic device such as an organic EL element is manufactured. It is preferable that the dispersion of the self-dispersing polymer do not contain, for example, a surfactant (emulsifier) or a plasticizer which controls a film forming temperature.

The glass transition temperature (Tg) of the dissociable group-containing self-dispersing polymer is 25° C. to 150° C., preferably 30° C. to 110° C.

The glass transition temperature being 25° C. or more improves a film forming property of coatings and surface smoothness of transparent electrodes, and hence prevents degradation of performance of elements due to deformation of coatings in an environmental test of transparent electrodes and/or electronic devices such as organic EL elements carried out at a high temperature. Further, the glass transition temperature being 150° C. or less improves homogeneity and surface smoothness of the transparent conductive layer, which is composed of the conductive polymer and the self-dispersing polymer, and improves performance of elements.

The glass transition temperature is measured at a temperature rise rate of 10° C./min with a differential scanning calorimeter (Model DSC-7 manufactured by PerkinElmer Inc.) in conformity with JIS K 7121-1987.

The dissociable group used for the dissociable group-containing self-dispersing polymer is not particularly limited to but includes anionic groups (sulfonic acid and salt thereof, carboxylic acid and salt thereof, phosphoric acid and salt thereof, etc.) and cationic groups (ammonium salt, etc.). The dissociable group is preferably an anionic group in terms of compatibility with the conductive polymer solution.

The amount of the dissociable group may be any as far as the self-dispersing polymer is dispersible in an aqueous solvent, preferably an amount as small as possible in terms of process adequacy so that a drying load is reduced. A counter species used for an anionic group or a cationic group is not particularly limited, but it is preferably hydrophobic and exists at a small amount in terms of performance of transparent electrodes and/or organic EL elements when the transparent electrodes and/or the organic EL elements are stacked.

Examples of the principal skeleton of the dissociable group-containing self-dispersing polymer include polyethylene, polyethylene-polyvinyl alcohol (PVA), polyethylene-polyvinyl acetate, polyethylene-polyurethane, polybutadiene, polybutadiene-polystyrene, polyamide (nylon), polyvinylidene chloride, polyester, polyacrylate, polyacrylate-polyester, polyacrylate-polystyrene, polyvinyl acetate, polyurethane-polycarbonate, polyurethane-polyether, polyurethane-polyester, polyurethane-polyacrylate, silicone, silicone-polyurethane, silicone-polyacrylate, polyvinylidene fluoride-polyacrylate and polyfluoroolefin-polyvinyl ether. Further examples thereof include copolymers composed of these skeletons as the base and other monomer used thereon. Of these, polyester resin emulsion and polyester-acrylic resin emulsion each having the ester skeleton, acrylic resin emulsion having the acrylic skeleton, and polyethylene resin emulsion having the ethylene skeleton are preferable.

Commercially-available products usable include: Yodosol AD-176 and AD-137 (acrylic resin, manufactured by Henkel Japan Ltd.); Vylonal MD-1200, MD-1245 and MD-1500 (polyester resin, manufactured by Toyobo Co., Ltd.); and PLAS COAT RZ570, PLAS COAT Z561, PLAS COAT Z565, PLAS COAT Z687 and PLAS COAT Z690 (polyester resin, manufactured by Goo Chemical Co., Ltd.). The d5ispersions of the above dissociable group-containing self-dispersing polymers each dispersible in an aqueous solvent can be used individually or in combination.

(Hydroxy Group-Containing Polymer)

The hydroxy group-containing polymer is a polymer having a hydroxy group.

The ratio of the hydroxy group-containing polymer to the conductive polymer of the transparent conductive layer is, to 100 parts by mass of the conductive polymer, preferably 30 parts by mass to 900 parts by mass of the hydroxy group-containing polymer and, in terms of current leakage prevention and transparency, far preferably 100 parts by mass or more of the hydroxy group-containing polymer.

The hydroxy group-containing polymer preferably has absorption of an absorbance of 0.1 or more at 2.5 to 3.0 μm. Here, the absorbance is an absorbance of a sample when the sample is applied onto a substrate in such a way as to be a thickness to use. Having an absorption region around 3.0 μm, which is mainly used in infrared rays that are used in the drying step, makes it easy to remove the solvent from the coating for forming the transparent conductive layer.

Further, having absorption at a wavelength region different from that of the resin film constituting the substrate makes it possible to selectively use a wavelength which hardly damages the substrate.

(Carbon Nanotube)

The carbon nanotube(s) used in the transparent conductive layer may be single-walled carbon nanotube(s) (SWNT) or multi-walled carbon nanotube(s) (MWNT), and the diameter and length thereof are not particularly limited. As the multi-walled carbon nanotube(s), double-walled carbon nanotube(s) is preferably used. Basically, the carbon nanotube(s) can be synthesized by any method; to be specific, for example, by laser ablation, electrical arc discharge, chemical vapor deposition (CVD) or the like. (Refer to, for example, Chem. Phys. Lett. 2002, 358, 213.)

As the method for forming the transparent conductive layer using the carbon nanotube, first, the carbon nanotube is dispersed, for example, in an aqueous liquid, an organic liquid, or a mixed liquid of an aqueous liquid and an organic liquid, by ultrasonication or the like and kept in this dispersed state, so that a carbon nanotube dispersion is prepared. If the carbon nanotube is dispersed in an aqueous liquid, use of a dispersant can produce an excellent dispersed state. As the dispersant, at least one type among FSN-100, Triton X-100, CMC, CHCl3, SDSA, SDBS, SDS, 2198A, FSO-100 and so forth is preferably used. As the organic liquid, at least one type of liquid among ethanol, methanol, chloroform, dimethylformamide, 1,2-dichlorobenzene, dichloroethane, isopropyl alcohol and γ-butyrolactone, which are organic solvents, is preferably used.

Next, thus-prepared carbon nanotube dispersion is applied onto the substrate. If the carbon nanotube dispersion using the above organic liquid is used, the transparent conductive layer can be formed by applying the carbon nanotube dispersion onto the substrate and then drying and removing the solvent. If the carbon nanotube dispersion using the above aqueous liquid and also using the dispersant is used, the transparent conductive layer having improved conductivity between the carbon nanotubes can be formed by applying the carbon nanotube dispersion onto the substrate, drying and removing the liquid component of the applied carbon nanotube dispersion, and then cleaning and removing the remaining dispersant.

[Gas Barrier Layer]

In a transparent electrode, if a small amount of moisture or oxygen enters its conductive metal layer, its properties, for example, on resistance, decreases. Further, if this transparent electrode is applied to the below-described organic EL element, and a small amount of moisture or oxygen enters the organic EL element, its properties readily decrease. It is effective to form, on the transparent resin substrate, a gas barrier layer having a high shielding property against moisture and oxygen in order to prevent moisture and oxygen from diffusing into the element through the transparent resin substrate.

As the gas barrier property of the gas barrier layer, it is preferable that a water vapor permeability (25±0.5° C. and a relative humidity of (90±2)%) determined by a method in conformity with JIS K 7129-1992 be 1×10⁻³ g/(m²·24 h) or less, and far preferable that an oxygen permeability determined by a method in conformity with JIS K 7126-1987 be 1×10⁻³ mL/m²·24h·atm or less.

The composition, structure and forming method of the gas barrier layer are not particularly limited. For example, a film containing an inorganic compound such as silica and formed by vacuum deposition or CVD can be used.

Alternatively, for example, a film formed by applying and drying an application liquid containing a polysilazane compound and then carrying out oxidation by ultraviolet irradiation under a nitrogen atmosphere containing oxygen and water vapor can be used. Before the gas barrier layer is formed, pretreatment may be carried out on the surface of the transparent resin substrate with a silane coupling agent or the like in order to improve adhesiveness to the transparent resin substrate.

The gas barrier layer may be composed of a single layer or have a multilayer structure composed of two or more layers. In the case where the gas barrier layer has the multilayer structure, the multilayer structure may be composed of an inorganic compound or formed as a hybrid coating composed of an inorganic compound and an organic compound. Further, a stress relief layer may be inserted into the gas barrier layer.

Regardless of a single layer or layers stacked, the thickness of one gas barrier layer is preferably 30 nm to 1,000 nm, far preferably 30 nm to 500 nm and particularly preferably 90 nm to 500 nm. When the thickness is 30 nm or more, thickness uniformity is excellent, and an excellent barrier property is obtained, whereas when the thickness is 1,000 nm or less, it hardly happens that cracks are suddenly made by bending, and the internal stress in film forming is kept from increasing, so that defects can be prevented from being generated.

As the method for applying the polysilazane compound, an appropriate method can be selected. Examples of the applying method include various types of printing such as roller coating, bar coating, dip coating, spin coating, casting, die coating, blade coating, curtain coating, spray coating and doctor coating, and various types of coating such as gravure printing, flexographic printing, offset printing, screen printing and inkjet printing. In the case where the gas barrier layer is preferably formed in a pattern, gravure printing, flexographic printing, offset printing, screen printing and inkjet printing are preferable.

The polysilazane used in the gas barrier layer is a polymer having a silicon-nitrogen bond and is a ceramic precursor inorganic polymer exemplified by SiO₂, Si₃N₄ and their intermediate solid solution SiOₓN_{y} composed of Si—N, Si—H, N—H and/or the like.

In the case where a resin substrate is used, as described in Japanese Patent Application Publication No. 8-112879, one which is modified to silica by becoming ceramic at a relatively low temperature is preferable, and one represented by the following General Formula (1) can be preferably used.

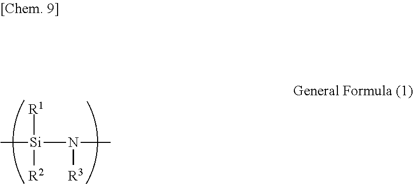

In General Formula (1), R¹, R² and R³ each represent a hydrogen atom, an alkyl group, an alkenyl group, a cycloalkyl group, an aryl group, an alkylsilyl group, an alkylamino group or an alkoxy group.

For perhydropolysilazane, R¹, R² and R³ are all hydrogen atoms, and for organopolysilazane, at least one of R¹, R² and R³ is an alkyl group, an alkenyl group, a cycloalkyl group, an aryl group, an alkylsilyl group, an alkylamino group or an alkoxy group. In terms of compactness as the barrier film to be obtained, perhydropolysilazane, for which R¹, R² and R³ are all hydrogen atoms, is particularly preferable.

<<Method for Manufacturing Transparent Electrode>>

The method for manufacturing the transparent electrode of the present invention has: a step of forming a metal adhesion layer on a substrate; a step of forming a thin metal wire(s) on the metal adhesion layer using a metal nanoparticle or metal complex ink, thereby forming a conductive metal layer; and a step of forming a transparent conductive layer on the substrate, the metal adhesion layer and the conductive metal layer. Preferably, in the step of forming a conductive metal layer, after the thin metal wire(s) is formed, the thin metal wire(s) is plated, whereby the conductive metal layer is formed.

If a gas barrier layer is provided, the step of forming a gas barrier layer described above can be applied thereto. To the step of forming a thin metal wire(s), the above method can be applied. To the step of forming a metal adhesion layer, the above method can be applied according to a variety of materials contained in the metal adhesion layer.

The step of forming a transparent conductive layer has a preparing step of preparing an application liquid for forming a transparent conductive layer, an applying step of forming a coating using the prepared application liquid, and a drying step of drying the formed coating.

[Preparation of Application Liquid]

First, in the step of forming a transparent conductive layer, an application liquid containing a conductive material is prepared. For example, an application liquid composed of fine particles of the above transparent conductive material dispersed in a solvent or an application liquid composed of the above conductive polymer and nonconductive polymer dispersed in a solvent is prepared. The solvent contains the above aqueous solvent and a high boiling point solvent. It is preferable to contain the below-described polar solvent.

(Aqueous Solvent)

As the aqueous solvent, an aqueous solvent which disperses the above dissociable group-containing self-dispersing polymer can be used. Examples thereof include water (distilled water and deionized water included); alcoholic solvents such as methanol and ethanol; and a mixed solvent acid of water and alcohol; an aqueous solution containing alkali, salt or the like; a water-containing organic solvent; and a hydrophilic organic solvent.

(High Boiling Point Solvent)

The application liquid for forming the transparent conductive layer contains a high boiling point solvent, the boiling point of which is higher than that of an aqueous solvent. Containing the high boiling point solvent can effectively reduce surface tension of the application liquid without reducing dispersion stability of the conductive polymer in the application liquid and achieve necessary and sufficient wettability thereof on the substrate, and also achieve a stable discharge property of the application liquid when applied by the inkjet method.

As the high boiling point solvent, glycolether is preferably used. It is preferable that glycolether be water-soluble and have a surface tension of 40 mN/m or less, preferably 35 mN/m or less and far preferably 30 mN/m or less.

The added amount of the glycolether can be determined on the basis of the surface tension of the application liquid and is, to the total weight of the application liquid, preferably 5 to 30 percent by mass. When the added amount is 5 percent by mass or more, the surface tension reducing effect is reduced and wettability of the application liquid to the substrate is improved, whereas when the added amount is 30 percent by mass or less, dispersion stability of the application liquid and application uniformity thereof by inkjet printing are improved.

Examples of the glycolether include ethylene glycol alkyl ether, diethylene glycol alkyl ether, triethylene glycol alkyl ether, propylene glycol alkyl ether, dipropylene glycol alkyl ether and tripropylene glycol alkyl ether. In terms of viscosity, surface tension and dispersion stability of the application liquid, ethylene glycol monoalkyl ether and propylene glycol monoalkyl ether are preferable.

Examples of the ethylene glycol monoalkyl ether and the propylene glycol monoalkyl ether include ethylene glycol monomethyl ether, ethylene glycol monoethyl ether, ethylene glycol monopropyl ether, ethylene glycol monobutyl ether, propylene glycol monomethyl ether, propylene glycol monoethyl ether, propylene glycol monopropyl ether and propylene glycol monobutyl ether. In particular, ethylene glycol monobutyl ether and propylene glycol monopropyl ether are preferable.

It is preferable to contain a polar solvent as the high boiling point solvent. The application liquid containing a polar solvent can keep itself stable without reducing dispersion stability of the dissociable group-containing self-dispersing polymer therein, and hence can be stably discharged when applied by the inkjet method.

The polar solvent usable has a dielectric constant of 25 or more, preferably 30 or more and far preferably 40 or more. Examples thereof include ethylene glycol, diethylene glycol, triethylene glycol, propylene glycol, dipropylene glycol, butanediol, pentanediol, glycerin, dimethylformamide, dimethylacetamide, N-methylpyrrolidone and dimethyl sulfoxide. In particular, propylene glycol and ethylene glycol are preferable in terms of a drying/removal property with infrared rays, stability of the application liquid, a discharge property thereof by inkjet printing, conductivity thereof and so forth.

The added amount of the polar solvent can be determined in terms of stability of the application liquid and is, to the total weight of the application liquid, preferably 5 to 40 percent by mass. When the added amount is 5 percent by mass or more, the stabilization effect of the application liquid is improved, whereas when the added amount is 40 percent by mass or less, surface tension of the application liquid is not too high and wettability thereof to the substrate is improved.

The dielectric constant of the solvent is measurable, for example, with a liquid dielectric constant meter Model 871 (manufactured by Nihon Rufuto Co., Ltd.).

[Applying Step]

Next, the application liquid prepared as described above is applied onto the thin metal wires-formed surface of the substrate. Thus, a coating containing a conductive material is formed thereon.

For forming the coating, in addition to the above printing methods such as gravure printing, flexographic printing and screen printing, applying methods such as roller coating, bar coating, dip coating, spin coating, casting, die coating, blade coating, bar coating, gravure coating, curtain coating, spray coating, doctor coating and the inkjet method can be used. In particular, in the case where the application liquid is disposed on the thin metal wires, by applying the application liquid by the inkjet method and drying the application liquid by infrared ray irradiation, stable thickness distribution of the application liquid, high surface smoothness and high patterning accuracy can be obtained.

[Drying Step]

The formed coating is irradiated with infrared rays and thereby dried. The solvent contained in the coating is removed by drying, and accordingly the transparent conductive layer is formed on the substrate. Although the infrared ray irradiation method is not particularly limited, use of the below-described infrared ray (IR) drying unit is preferable. The drying is carried out in a drying tank where the water concentration is 100 ppm or less. The water concentration of the drying tank is defined by the water concentration at the end of drying in the tank, which carries out the drying.

In the step of irradiating the coating with infrared rays, the irradiation is carried out with infrared rays having a ratio of the spectral radiance at a wavelength of 5.8 μm to the spectral radiance at a wavelength of 3.0 μm of 5% or less. In the infrared rays used for drying the coating, the ratio of the spectral radiance at a wavelength of 5.8 μm to the spectral radiance at a wavelength of 3.0 μm is 5% or less, preferably 3% or less, far preferably 1% or less and most preferably 0.5% or less.

The aqueous solvent preferably used for the application liquid for forming the transparent conductive layer has a strong absorption wavelength owing to OH stretching vibration at around 3.0 μm. On the other hand, the polyester resin film or the like preferably used for the substrate has almost no absorption wavelength at around 3.0 μm of the infrared wavelength region, but has a strong absorption wavelength at 5.8 μm or more of the infrared wavelength region. Hence, irradiating the coating with the infrared rays having a ratio of the spectral radiance at a wavelength of 5.8 μm to the spectral radiance at a wavelength of 3.0 μm of 5% or less can effectively dry the coating and also can prevent damage to the substrate.

Further, drying in the drying tank where the water concentration is 100 ppm or less can reduce the amount of the remaining water and high boiling point solvent in the transparent conductive layer. Reducing the remaining solvent(s) in the transparent conductive layer makes the microscopic structure or morphology of the transparent conductive layer composed of the conductive polymer and the non-conductive polymer excellent, and can make the transparent electrode 10 have a lower resistance and can improve stability of the transparent electrode 10.

Further, drying, by the above drying, the transparent electrode 10 such that the amount of the water molecules is 2 mg/m² or less and the amount of the high boiling point solvent is 0.05 mg/m² or less, the amounts being measured by thermal desorption spectroscopy when the transparent electrode 10 is heated to 180° C., can make the transparent electrode have a lower resistance and can improve stability of the transparent electrode 10.

Hence, when the above transparent electrode is applied to an electronic device, the effects due to the improved morphology of the conductive metal layer of the transparent electrode can be obtained. For example, if the above transparent electrode is applied to a transparent electrode of an organic EL element, effects such as reduction in driving voltage, reduction in emission unevenness and increase in lifetime can be obtained. Further, if the above transparent electrode is applied to a transparent electrode of a touchscreen, effects such as reduction in resistance and improvement of optical transparency can be obtained.

<<Transparent Electrode Manufacturing Apparatus>>

Next, a transparent electrode manufacturing apparatus to which the above method for manufacturing a transparent electrode(s) is applicable is described. The transparent electrode manufacturing apparatus has at least a drying tank for drying coatings to carry out the step of drying the coating containing the conductive material and the solvent.

The drying tank is provided with an IR drying unit for irradiating coatings with infrared rays. The drying tank is configured to keep the water concentration at the end of drying the coating at 100 ppm or less.

To devices of the transparent electrode manufacturing apparatus, the devices being used for the steps for manufacturing a transparent electrode(s) other than the step of drying the coating, publicly-known configurations are applicable. Further, the step of drying the coating can be carried out with the IR drying unit described in Japanese Patent Application Publication No. 2014-175560.

<<Electronic Device>>

The above transparent electrode is applicable to a variety of electronic devices. For example, the transparent electrode is applicable to a transparent electrode of various optoelectronic devices such as a liquid crystal display element, an organic luminescence element, an inorganic electroluminescence element, electronic paper, an organic solar cell and an inorganic solar cell, and electronic devices such as an electromagnetic shield and a touchscreen. In particular, it can be preferably used as a transparent electrode of an organic electroluminescence element (organic EL element). The organic EL element can be used for a self-emitting display, a back light for a liquid crystal device, a light and so forth. The organic EL element is preferably used as an electronic device for illumination because it can uniformly emit light with no unevenness. Hereinafter, as an example of the electronic device to which the above transparent electrode is applied, the structure of an organic EL element having the transparent electrode is described.

<<Organic Electroluminescence Element>>

An organic EL element includes at least a first electrode, an organic functional layer(s) and a second electrode arranged in this order. For example, in an organic EL element, the transparent electrode is preferably used as the anode. For the organic functional layer, the second electrode (cathode) and so forth, publicly-known materials, structures and so forth generally used in an organic EL element can be used.

There are various examples of the structure of the organic EL element, including anode/organic luminescent layer/cathode, anode/hole transport layer/organic luminescent layer/electron transport layer/cathode, anode/hole injection layer/hole transport layer/organic luminescent layer/electron transport layer/cathode, anode/hole injection layer/organic luminescent layer/electron transport layer/electron injection layer/cathode, and anode/hole injection layer/organic luminescent layer/electron injection layer/cathode.

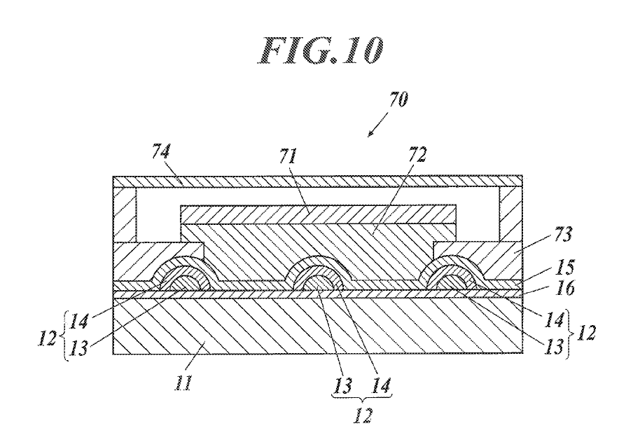

FIG. 10 shows an example of the structure of an organic EL element having the transparent electrode. As shown in FIG. 10, an organic EL element 70 has a transparent electrode 10 which includes a substrate 11, a metal adhesion layer 16, a conductive metal layer 12 (thin metal wires 13 and a plating layer(s) 14) and a transparent conductive layer 15. On the side edge parts of the substrate of the transparent electrode, extraction electrodes 73 are formed.

The extraction electrodes 73 are electrically connected to the conductive metal layer 12 and the transparent conductive layer 15. On the transparent conductive layer 15 of the transparent electrode 10, an organic functional layer 72 is formed.

The organic functional layer 72 has a positive hole transport layer, a luminescent layer, a positive hole block layer, an electron transport layer and so forth. On the organic functional layer, a counter electrode 71 is formed. The counter electrode is an electrode facing the transparent electrode and having a polarity opposite to that of the transparent electrode.

The organic EL element is sealed with a sealing member 74 with parts of the extraction electrodes exposed, so that the transparent electrode and the organic functional layer are covered with and protected by the sealing member 74.

Examples of a luminescent material and a dopant material used for the organic luminescent layer 72 include but are not limited to anthracene, naphthalene, pyrene, tetracene, coronene, perylene, phthaloperylene, naphthaloperylene, diphenylbutadiene, tetraphenylbutadiene, coumarin, oxadiazole, bisbenzoxazoline, bisstyryl, cyclopentadiene, quinoline metal complex, tris(8-hydroxyquinolinate) aluminum complex, tris(4-methyl-8-quinolinate) aluminum complex, tris(5-phenyl-8-quinolinate) aluminum complex, aminoquinoline metal complex, benzoquinoline metal complex, tri-(p-terphenyl-4-yl)amine, 1-aryl-2,5-di(2-thienyl)pyrrole derivative, pyran, quinacridone, rubrene, distylbenzene derivative, distylarylene derivative, and various fluorescent dyes, rare earth metal complexes and phosphorescent materials. It is preferable to contain, of these compounds, 90 to 99.5 parts by mass of a luminescent material and 0.5 to 10 parts by mass of a dopant material.

The organic luminescent layer is formed of any of the above materials and so forth by a publicly-known method, and examples thereof include vapor deposition, application and transfer. The thickness of the organic luminescent layer is preferably 0.5 to 500 nm and particularly preferably 0.5 to 200 nm.

### EXAMPLES

Hereinafter, the present invention is more specifically described with Examples. However, the present invention is not limited thereto. Note that “parts” and “%” used in Examples stand for “parts by mass” and “percent by mass (mass %)”, respectively, unless otherwise specified.

### First Example

### <<Manufacture of Transparent Electrode 101>>

### <Formation of Thin Metal Wires>

A transparent PET substrate (150 mm×150 mm) was prepared. A nano-paste containing silver nanoparticles for inkjet (NPS-JL manufactured by Harima Chemicals Group, Inc.; hereinafter may be called “Ag nanoparticle ink”) was applied onto an area of 100 mm×100 mm of the substrate by an inkjet apparatus in a stripe pattern having a line width of 50 μm and a pitch of 1 mm. Thus, thin metal wires of the thin metal wire pattern were formed. The thin metal wires were inclined at 45° to the substrate (see FIG. 2E). At the time, in order to obtain a sufficient height, the application was carried out three times such that the nano-paste was piled.

As the inkjet apparatus, a desktop-type robot Shotmaster-300 (manufactured by Musashi Engineering, Inc.) provided with an inkjet head(s) KM512SHX manufactured by Konica Minolta, Inc. was used, and controlled by an inkjet evaluation system EB150 (manufactured by Konica Minolta, Inc.).

Next, to the substrate, on which the thin metal wires had been formed, xenon light was emitted for calcination with PulseForge 1300 manufactured by NovaCentrix.

Xenon light took pulse emission of 250 μs on a cycle of 500 μs, and was adjusted to apply an energy of 1500 mJ/cm² and emitted.

The thin metal wire pattern was measured with a high-luminance noncontact three-dimensional surface roughness meter Wyko NT9100 (manufactured by Nihon Veeco K.K.). The wire width of the pattern was 50 μm, and the average height thereof was 1 μm.

### <Formation of Transparent Conductive Layer>

A transparent conductive polymer PEDOT/PSS (Clevios PH1000, manufactured by Heraeus, 1.2% liquid) and polyhydroxyacrylate (PHEA) (20% liquid) were mixed at a solid content ratio of 15:85, 70 parts by mass of this mixture was mixed with 15 parts by mass of propylene glycol and 12 parts by mass of ethylene glycol monobutyl ether, and then water was added thereto so that the resulting product reached 100 parts by mass. Thus, an application liquid for forming a transparent conductive layer was prepared.

PHEA was synthesized as described below, and an aqueous dispersion with 20 percent by mass thereof as prepared.

In a 300 mL recovery flask, 5.0 g (43.1 mmol, Fw: 116.12) of 2-hydroxyethyl acrylate (manufactured by Tokyo Chemical Industry Co., Ltd.) and 0.7 g (4.3 mmol, Fw: 164.21) of 2,2′-azobis(2-methylisopropylonitrile) were poured, 100 mL of tetrahydrofuran (THF) was added thereto, and the resulting product was heated to reflux for eight hours.

Thereafter, the solution was cooled to room temperature and dropped into 2.0 L of methyl-ethyl-ketone which had been stirred hard. After the reaction solution was stirred for one hour, methyl-ethyl-ketone was decanted, and the polymer(s) which had adhered to the wall was cleaned with 100 mL of methyl-ethyl-ketone three times.

The obtained polymer was dissolved in 100 mL of THF, the resulting product was moved to a 200 mL flask, and THF was subjected to vacuum distillation with a rotary evaporator. Thereafter, depressurization was carried out at 80° C. for three hours, so that the remaining THF was distillated, and 4.1 g (yield of 82%) of PHEA having a number average molecular weight of 57,800 and a molecular weight distribution of 1.24 was produced.

Next, the application liquid prepared for forming a transparent conductive layer was applied by inkjet printing onto an area of 102 mm×102 mm of the substrate, on which the thin metal wires had been formed. The thickness of the transparent conductive layer was 150 nm.

Next, the substrate, onto which the transparent conductive layer had been applied, was moved to a nitrogen-filled glovebox which had been adjusted to be a dew point of −80° C. or less and an oxygen concentration of 1 ppm or less, and was dried with an infrared ray heater under the conditions of a filament temperature of 1,500° C. and a treatment time of ten minutes. Thus, a transparent electrode 101 was obtained.

The infrared ray heater was one constituted of a heater (1,000 W, color temperature of 2,500 K) manufactured by USHIO Inc. provided with an air-cooling mechanism in a quartz glass duplex tube with reference to Japanese Patent No. 4790092. Distance between the heater and the sample(s) was 100 mm.

<<Manufacture of Transparent Electrode 102>>

### <Formation of Thin Metal Wires>

A transparent PET substrate (150 mm×150 mm) was prepared. An Ag nanoparticle ink (NPS manufactured by Harima Chemicals Group, Inc.) was applied onto an area of 100 mm×100 mm of the substrate by a screen printing apparatus in a stripe pattern having a line width of 50 μm and a pitch of 1 mm. Thus, thin metal wires of the thin metal wire pattern were formed.

Next, to the substrate, on which the thin metal wires had been formed, xenon light was emitted for calcination with PulseForge 1300 manufactured by NovaCentrix. The emission conditions of xenon light were the same as those in manufacture of the transparent electrode 101.

The thin metal wire pattern was measured with a high-luminance noncontact three-dimensional surface roughness meter Wyko NT9100 (manufactured by Nihon Veeco K.K.). The wire width of the pattern was 50 μm, and the average height thereof was 1.0 μm.

<Formation of Transparent Conductive Layer>

A transparent conductive layer was formed in the same manner as that of the transparent electrode 101. Thus, a transparent electrode 102 was obtained.

<<Manufacture of Transparent Electrode 103>>

### <Formation of Thin Metal Wires>

Thin metal wires were formed in the same manner as those of the transparent electrode 101.

<Formation of Transparent Conductive Layer>

The substrate, on which the thin metal wires had been formed, was set in a commercially-available DC magnetron sputtering device.

Once a vacuum chamber was vacuumed to 1×10⁻³ Pa or less, argon gas and water vapor were introduced thereto to be a pressure of 3 Pa. At the time, the ratio of argon gas to water vapor was 100:1. Film forming of ITO was carried out at an output of 300 W, and accordingly a transparent conductive layer having a thickness of 150 nm was formed.

Thus, a transparent electrode 103 was obtained.

<<Manufacture of Transparent Electrode 104>>

### <Formation of Thin Metal Wires>

Thin metal wires were formed in the same manner as those of the transparent electrode 102.

<Formation of Transparent Conductive Layer>

A transparent conductive layer was formed in the same manner as that of the transparent electrode 103.

<<Manufacture of Transparent Electrode 105>>

### <Formation of Metal Adhesion Layer>

First, tertiary animo group-containing polyol (Z) was synthesized. Into a four-neck flask provided with a thermometer, a stirrer, a reflux cooling tube and a dropper, 543 parts by mass of polyethylene glycol-diglycidyl ether (epoxy equivalent: 185 g/equivalent) was poured, and then nitrogen purge of the flask was carried out. Next, until the temperature in the flask reached 70° C., heating was carried out with an oil bath, and then 380 parts by mass of di-n-butylamine was dropped with the dropper, taking 30 minutes. After the dropping, reaction was carried out at 70° C. for ten hours. After the reaction ended, it was confirmed using an infrared spectrophotometer (FT/IR-460Plus manufactured by JASCO Corporation) that an absorption peak around 842 cm⁻¹ caused by the epoxy group of the product of the reaction disappeared. Thus, tertiary animo group-containing polyol (Z) (amine equivalent: 315 g/equivalent, hydroxy group equivalent: 315 g/equivalent) was prepared.

Thereafter, to the four-neck flask provided with a thermometer, a stirrer, a reflux cooling tube and a dropper, 1,070 parts by mass of polyester polyol (number average molecular weight of 2,000) obtained by reaction of neopentyl glycol, 1,4-butanediol, terephthalic acid and adipic acid and 770 parts by mass of ethyl acetate were added, and stirred with the temperature being increased to 70° C. After the stirring and thereby mixing, 281 parts by mass of dicyclohexylmethane 4,4′-diisocyanate and 0.2 parts by mass of tin 2-ethylhexanoate were added thereto and reacted at 70° C. for two hours.

After the reaction ended, 84 parts by mass of tertiary animo group-containing polyol (Z) was added thereto and reacted for four hours, and then cooled to 55° C. Thus, an isocyanate-terminated urethane prepolymer solution was prepared. Next, to the urethane prepolymer solution, 48 parts by mass of N-aminoethylethanolamine was added, and chain elongation reaction was carried out for one hour.

Next, 1,650 parts by mass of ethyl acetate and 23 parts by mass of acetic acid were added thereto, kept at 45° for one hour and then cooled to 40° C., and 3,850 parts by mass of deionized water was added thereto. Thus, an aqueous dispersion was prepared. This aqueous dispersion was subjected to vacuum distillation. Thus, a metal adhesion layer forming-application liquid composed of a cationic urethane resin composition having a nonvolatile content of 30 percent by mass was prepared.

To the whole surface of a transparent PET substrate (150 mm×150 mm), the surface on which thin metal wires were to be formed, the prepared metal adhesion layer-forming composition was applied by bar coating and dried with a hot air dryer at 70° C. for five minutes in such a way as to be a dry thickness of 1 μm. Thus, a metal adhesion layer was formed on the substrate.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 101. Thus, a transparent electrode 105 was obtained.

<<Manufacture of Transparent Electrode 106>>

### <Formation of Metal Adhesion Layer>

A metal adhesion layer was formed in the same manner as that of the transparent electrode 105.

<Formation of Thin Metal Wires>

Thin metal wires were formed in the same manner as those of the transparent electrode 102.

<Formation of Transparent Conductive Layer>

A transparent conductive layer was formed in the same manner as that of the transparent electrode 101. Thus, a transparent electrode 106 was obtained.

<<Manufacture of Transparent Electrode 107>>

### <Formation of Metal Adhesion Layer>

A metal adhesion layer was formed in the same manner as that of the transparent electrode 105.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 107 was obtained.

<<Manufacture of Transparent Electrode 108>>

### <Formation of Metal Adhesion Layer>

A metal adhesion layer was formed in the same manner as that of the transparent electrode 105.

<Formation of Thin Metal Wires>

Thin metal wires were formed in the same manner as those of the transparent electrode 102.

<Formation of Transparent Conductive Layer>

A transparent conductive layer was formed in the same manner as that of the transparent electrode 103. Thus, a transparent electrode 108 was obtained.

<<Manufacture of Transparent Electrode 109>>

### <Formation of Metal Adhesion Layer>

To the whole surface of a transparent PET substrate (150 mm×150 mm), the surface on which thin metal wires were to be formed, an MEK solution with 0.05 percent by mass of P-4 was applied by an inkjet apparatus and heated to be dried at 110° C. for one hour. Thus, a metal adhesion layer having a thickness of 1 μm and containing a polymer formed from P-4 was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 109 was obtained.

<<Manufacture of Transparent Electrode 110>>

### <Formation of Metal Adhesion Layer>

A transparent PET substrate (150 mm×150 mm) was prepared. An MEK solution with 0.05 percent by mass of P-4 was applied only onto parts where thin metal wires were to be formed in an area of 100 mm×100 mm of the substrate by an inkjet apparatus in a stripe pattern having a line width of 50 μm and a pitch of 1 mm.

As the inkjet apparatus, a desktop-type robot Shotmaster-300 (manufactured by Musashi Engineering, Inc.) provided with an inkjet head(s) KM512SHX manufactured by Konica Minolta, Inc. was used, and controlled by an inkjet evaluation system EB150 (manufactured by Konica Minolta, Inc.).

After the MEK solution with P-4 was applied, it was heated to be dried at 110° C. for one hour. Thus, a metal adhesion layer having a thickness (height) of 1 μm and containing a polymer formed from P-4 was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 110 was obtained.

<<Manufacture of Transparent Electrode 111>>

### <Formation of Metal Adhesion Layer>

In a four-neck flask provided with a cooling tube, a stirrer, a thermometer and a nitrogen introducing tube, a vinyl monomer mixture containing 45 parts by mass of methyl methacrylate, 45 parts by mass of n-butyl acrylate, 5 parts by mass of 4-hydroxybutyl acrylate and 5 parts by mass of methacrylic acid and ethyl acetate were poured, and stirred in a nitrogen atmosphere with the temperature being increased to 50° C., and then 2.0 parts by mass of 2,2′-azobis(2-methylbutyronitrile) was poured therein and reacted for 24 hours, so that 500 parts by mass of a mixture (nonvolatile content of 20 percent by mass) containing a vinyl polymer having a weight average molecular weight of 400,000 and ethyl acetate was obtained.

Next, 500 parts by mass of the mixture and 22.5 parts by mass of a crosslinking agent composition 1 (nonvolative content of 20 percent by mass) containing a crosslinking agent 1 composed of nurate of hexamethylene diisocyanate and ethyl acetate were mixed. Thus, a metal adhesion layer-forming composition having a nonvolatile content of 20 percent by mass was obtained.

As a specimen used for measurement of the weight average molecular weight of the vinyl polymer, a filtrate was used, the filtrate being obtained by mixing 80 mg of the vinyl polymer and 20 ml of tetrahydrofuran, stirring the same for 12 hours and filtering the same with a 1 μm membrane-filter.

The measurement was carried out by gel permeation chromatography (GPC). As a measuring device, a high performance liquid chromatograph HLC-8220 manufactured by Tosoh Co. was used, and as a column, TSKgel GMH XL×4 column manufactured by Tosoh Co. was used. As an eluent, tetrahydrofuran was used, and the measurement was carried out with an RI detector.

To the whole surface of a transparent PET substrate (150 mm×150 mm), the surface on which thin metal wires were to be formed, the prepared metal adhesion layer-forming composition was applied by bar coating and dried with a hot air dryer at 100° C. for five minutes in such a way as to be a dry thickness of 1 μm. Thus, a metal adhesion layer was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 111 was obtained.

<<Manufacture of Transparent Electrode 112>>

### <Formation of Metal Adhesion Layer>

3-aminopropyltriethoxysilane and water were mixed to be 5 percent by mass and 95 percent by mass, respectively, and stirred at room temperature for one hour, so that a coating liquid was prepared. To the whole surface of a transparent PET substrate (150 mm×150 mm), the surface on which thin metal wires were to be formed, the coating liquid was applied by bar coating and dried at 100° C. for one minute in such a way as to be a dry thickness of 1 μm. Thus, a metal adhesion layer was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 112 was obtained.

<<Manufacture of Transparent Electrode 113>>

### <Formation of Metal Adhesion Layer>

1 part(s) by mass of TiO₂ particles (TiO₂ particles having a refractive index of 2.4 and an average particle size of 0.25 μm (JR600A manufactured by TAYCA Corporation)) was dispersed in 99 parts by mass of a mixed liquid of water, ethanol and methanol, so that an application liquid was prepared. To the whole surface of a transparent PET substrate (150 mm×150 mm), the surface on which thin metal wires were to be formed, the application liquid was applied by inkjet and dried at 60° C. for 30 minutes in the air in such a way as to be a dry thickness of 1 μm. Thus, a metal adhesion layer was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 113 was obtained.

<<Manufacture of Transparent Electrode 114>>

### <Formation of Metal Adhesion Layer>

1 part(s) by mass of ZnO particles (793361 manufactured by Aldrich, particle size of 10 to 15 nm, 2.5 wt % (crystalline ZnO in 2-propanol)) was dispersed in 99 parts by mass of a mixed liquid of water, ethanol and methanol, so that an application liquid was prepared. To the whole surface of a transparent PET substrate (150 mm×150 mm), the surface on which thin metal wires were to be formed, the application liquid was applied by inkjet and dried at 60° C. for 30 minutes in the air in such a way as to be a dry thickness of 1 μm. Thus, a metal adhesion layer was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 114 was obtained.

<<Manufacture of Transparent Electrode 115>>

### <Formation of Metal Adhesion Layer>

To the whole surface of a transparent PET substrate (150 mm×150 mm), the surface on which thin metal wires were to be formed, polyurethane latex (solid content of 3%) containing 10 percent by mass of TiO₂ particles (average particle size of 27 nm) and 0.3 percent by mass of 2-mercaptotriazole was applied by inkjet and dried at 60° C. for 30 minutes in the air in such a way as to be a dry thickness of 1 μm. Thus, a metal adhesion layer was formed.

<Formation of Thin Metal Wires>

Thin metal wires were formed in the same manner as those of the transparent electrode 101.

<Formation of Transparent Conductive Layer>

A transparent conductive layer was formed in the same manner as that of the transparent electrode 103. Thus, a transparent electrode 115 was obtained.

<<Manufacture of Transparent Electrode 116>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 101 except that the application in printing the thin metal wires was carried out one time. The average height was 0.3 μm.

<Formation of Plating Layer>

Next, silver plating was carried out to plate the thin metal wires with silver of 0.7 μm, so that the total average height together with the thin metal wires was 1 μm. Silver plating was carried out using a plating liquid of silver cyanide, potassium cyanide and potassium carbonate by an electrolytic method using the thin metal wires as an electrode(s) for electric power supply.

<Formation of Transparent Conductive Layer>

A transparent conductive layer was formed in the same manner as that of the transparent electrode 101. Thus, a transparent electrode 116 was obtained.

<<Manufacture of Transparent Electrode 117>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 117 was obtained.

<<Manufacture of Transparent Electrode 118>>

### <Formation of Metal Adhesion Layer>

A metal adhesion layer was formed in the same manner as that of the transparent electrode 105.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 118 was obtained.

<<Manufacture of Transparent Electrode 119>>

### <Formation of Metal Adhesion Layer>

A metal adhesion layer was formed in the same manner as that of the transparent electrode 111.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 119 was obtained.

<<Manufacture of Transparent Electrode 120>>

### <Formation of Metal Adhesion Layer>

A metal adhesion layer was formed in the same manner as that of the transparent electrode 112.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 120 was obtained.

<<Manufacture of Transparent Electrode 121>>

### <Formation of Metal Adhesion Layer>

A metal adhesion layer was formed in the same manner as that of the transparent electrode 113.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 121 was obtained.

<<Manufacture of Transparent Electrode 122>>

### <Formation of Metal Adhesion Layer>

A metal adhesion layer was formed in the same manner as that of the transparent electrode 114.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 122 was obtained.

<<Manufacture of Transparent Electrode 123>>

### <Formation of Metal Adhesion Layer>

A metal adhesion layer was formed in the same manner as that of the transparent electrode 115.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 123 was obtained.

<<Manufacture of Transparent Electrode 124>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116.

<Formation of Plating Layer>

A plating layer was formed in the same manner as that of the transparent electrode 116.

<Formation of Transparent Conductive Layer>

First, single-walled carbon nanotube(s) (SWNT) was dispersed in an aqueous solution with 1 percent by mass of SDS, so that 0.1 mg/mL of an SWNT dispersion was prepared. To the substrate, on which the thin metal wires had been formed, a layer of the SWNT dispersion was formed by bar coating and dried at 60° C. for 30 minutes in the air, and accordingly a transparent conductive layer having a thickness of 150 nm was formed.

Thus, a transparent electrode 124 was obtained.

<<Manufacture of Transparent Electrode 125>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116.

<Formation of Plating Layer>

An activator (Ace Clean A220 manufactured by Okuno Chemical Industries Co., Ltd.) was applied onto the thin metal wires to activate plating nuclei.

Next, an electroless copper plating agent (OPC-750 electroless copper M manufactured by Okuno Chemical Industries Co., Ltd.) was applied onto the activated surface, and electroless copper plating was carried out under the conditions of 20° C. and 20 minutes.

<Formation of Transparent Conductive Layer>

A transparent conductive layer was formed in the same manner as that of the transparent electrode 103. Thus, a transparent electrode 125 was obtained.

<<Manufacture of Transparent Electrode 126>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116.

<Formation of Plating Layer>

Next, copper plating was carried out to plate the thin metal wires with copper of 0.6 μm, and next nickel plating was carried out to plate the thin metal wires with nickel of 0.1 μm, so that the total average height together with the thin metal wires was 1 μm. For copper plating, a plating liquid of copper sulfate or sulfuric acid was used, and for nickel plating, a plating liquid of nickel chloride and hydrochloric acid was used. Both of copper plating and nickel plating were carried out by an electrolytic method using the thin metal wires as an electrode(s) for electric power supply.

<Formation of Transparent Conductive Layer>

A transparent conductive layer was formed in the same manner as that of the transparent electrode 103. Thus, a transparent electrode 126 was obtained.

<<Manufacture of Transparent Electrode 127>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116.

<Formation of Plating Layer>

Next, copper plating was carried out to plate the thin metal wires with copper of 0.7 μm, so that the total average height together with the thin metal wires was 1 μm. Copper plating was carried out using a plating liquid of copper sulfate and sulfuric acid by an electrolytic method using the thin metal wires as an electrode(s) for electric power supply.

<Formation of Transparent Conductive Layer>

A transparent conductive layer was formed in the same manner as that of the transparent electrode 103. Thus, a transparent electrode 127 was obtained.

<<Manufacture of Transparent Electrode 128>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 102 except that the application in printing the thin metal wires was carried out one time. The average height was 0.3 μm.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 128 was obtained.

<<Manufacture of Transparent Electrode 129>>

### <Formation of Metal Adhesion Layer>

A metal adhesion layer was formed in the same manner as that of the transparent electrode 109.

<Formation of Thin Metal Wires>

A silver nanoparticle ink (NPS manufactured by Harima Chemicals Group, Inc.) was applied by a letterpress reverse printing apparatus in a stripe pattern having a line width of 50 μm and a pitch of 1 mm. Thus, thin metal wires of the thin metal wire pattern were formed.

The height was measured and it was 0.3 μm.

The letterpress reverse printing is a method of applying a silver nanoparticle ink onto a blanket, thereby forming a silver nanoparticle ink-applied surface, and transferring the same to a substrate.

As the blanket, it is preferable to use a silicone blanket composed of silicone.

First, a silver nanoparticle ink is applied onto the blanket. Next, a letterpress plate provided with a plate corresponding to a predetermined pattern shape as needed is pressed, so that silver nanoparticles contained in the silver nanoparticle ink contacting the letterpress plate are transferred from the blanket to the surface of the letterpress plate.

Next, the blanket and a substrate are brought into contact with one another, so that the remaining silver nanoparticles on the blanket are transferred to the surface of the substrate. This method can form thin metal wires having a predetermined pattern.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 129 was obtained.

<<Manufacture of Transparent Electrode 130>>

### <Formation of Metal Adhesion Layer>

A metal adhesion layer was formed in the same manner as that of the transparent electrode 109.

<Formation of Thin Metal Wires>

Thin metal wires were formed by printing using the inkjet parallel line drawing method (hereinafter may be called “parallel line drawing method”) with an inkjet head(s) (KM512L manufactured by Konica Minolta, Inc., a standard droplet amount of 42 pl) under the following conditions with the substrate temperature being kept at 50° C.

| Printing Conditions: | | |
|---|---|---|
| Pitch in Nozzle Line Direction | 141 | μm |
| Dot-to-Dot Pitch in Scanning Direction | 60 | μm |
| Ink: | | |
| Concentration of Silver Nanoparticles | 1 | mass % |
| Concentration of Silicon Activator | 0.25 | mass % |
| 1,3-Butandiol | 8 | mass % |
| Deionized Water | 90.75 | mass % |

The height, wire width and pitch were measured, and they were 0.06 μm, 5.8 μm and 0.07 μm, respectively.

<Formation of Plating Layer>

Next, copper plating was carried out to plate the thin metal wires with copper of 0.44 μm, so that the total average height together with the thin metal wires was 0.5 μm. Copper plating was carried out using a plating liquid of copper sulfate and sulfuric acid by an electrolytic method using the thin metal wires as an electrode(s) for electric power supply.

<Formation of Transparent Conductive Layer>

A transparent conductive layer was formed in the same manner as that of the transparent electrode 103. Thus, a transparent electrode 130 was obtained.

<<Manufacture of Transparent Electrode 131>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116 except that a silver complex ink for inkjet (TEC-IJ-010) manufactured by InkTec Co., Ltd. was used instead of the silver nanoparticle ink.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 131 was obtained.

<<Manufacture of Transparent Electrode 132>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 129.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 132 was obtained.

<<Manufacture of Transparent Electrode 133>>

### <Formation of Metal Adhesion Layer>

A metal adhesion layer was formed in the same manner as that of the transparent electrode 109.

<Formation of Thin Metal Wires>

A nano-paste containing copper nanoparticles (hereinafter may be called “copper nanoparticle ink”) was prepared with reference to Japanese Patent Application Publication No. 2012-178334. Concentrations of resin and copper nanoparticles were adjusted such that the copper nanoparticle ink had a viscosity of about 10 mPa·sec.

Thin metal wires were formed in the same manner as those of the transparent electrode 116 except that the prepared copper nanoparticle ink was used instead of the silver nanoparticle ink.

<Formation of Plating Layer>

A plating layer was formed in the same manner as that of the transparent electrode 116.

<Formation of Transparent Conductive Layer>

A transparent conductive layer was formed in the same manner as that of the transparent electrode 103. Thus, a transparent electrode 133 was obtained.

<<Manufacture of Transparent Electrode 134>>

### <Formation of Metal Adhesion Layer>

A metal adhesion layer was formed in the same manner as that of the transparent electrode 109.

<Formation of Thin Metal Wires>

Thin metal wires were formed in the same manner as those of the transparent electrode 116.

<Formation of Plating Layer>

A plating layer was formed in the same manner as that of the transparent electrode 127.

<Formation of Transparent Conductive Layer>

The substrate, on which those up to the plating layer had been formed, was set in a commercially-available DC magnetron sputtering device.

Once a vacuum chamber was vacuumed to 1×10⁻³ Pa or less, argon gas and oxygen were introduced thereto to be a pressure of 0.4 Pa. At the time, the ratio of argon gas to oxygen was 100:1. Film forming of IZO was carried out at an output of 900 W, and accordingly a transparent conductive layer having a thickness of 150 nm was formed.

Thus, a transparent electrode 134 was obtained.

<<Evaluation Methods>>

Details of the manufactured transparent electrodes 101 to 134 are shown in TABLE 1 and TABLE 2. With respect to the transparent electrodes 101 to 134, the following evaluations were carried out. The evaluation results are shown in TABLE 3. In TABLE 1 and TABLE 2, “IJ” represents inkjet.

### (1) Measurement of Surface Resistance

Surface resistance was measured with a resistivity meter (MCP-T610 manufactured by Mitsubishi Chemical Analytech Co., Ltd.) by the 4-terminal method, 4-pin probe method and constant-current method.

### (2) Measurement of Transmittance

Transmittance was measured with HDN 7000 manufactured by Nippon Denshoku Industries Co., Ltd. on the basis of JIS K7361.

### (3) Measurement of Adhesiveness

A cellophane adhesive tape “CT24” manufactured by NICHIBAN Co., Ltd. was attached to the manufactured transparent electrodes and thereafter detached. The case where the thin metal wires did not come off was evaluated as “0” (circle, meaning good), whereas the case where the thin metal wires came off was evaluated as “x” (cross, meaning bad).

### (4) Measurement of Storability (Change Rate in Resistance and Change Rate in Transmittance)

As measurement of storability, the change rate in resistance and the change rate in transmittance were measured.

More specifically, resistance values and transmittances of each manufactured transparent electrode before and after the transparent electrode was stood still for 250 hours in a thermostat oven of 85° C. and a relative humidity of 4% or less were compared with one another. The measured values are shown by “(value after still standing for 250 hours)/(value before still standing for 250 hours)”.

TABLE 1

| | | | | CONDUCTIVE METAL LAYER | | | | |
|---|---|---|---|---|---|---|---|---|
| | | METAL ADHESION LAYER | | THIN METAL WIRE | | | | |
| | | | PRINTING | | PRINTING | HEIGHT | WIRE WIDTH | PITCH |
| *3 | SUBSTRATE | MATERIAL | METHOD | MATERIAL | METHOD | (μm) | (μm) | (mm) |
| 101 | PET | — | — | Ag NANOPARTICLE | IJ | 1.00 | 50.0 | 1.00 |
| 102 | PET | — | — | Ag NANOPARTICLE | SCREEN | 1.00 | 50.0 | 1.00 |
| 103 | PET | — | — | Ag NANOPARTICLE | IJ | 1.00 | 50.0 | 1.00 |
| 104 | PET | — | — | Ag NANOPARTICLE | SCREEN | 1.00 | 50.0 | 1.00 |
| 105 | PET | POLYURETHANE | BAR COATING | Ag NANOPARTICLE | IJ | 1.00 | 50.0 | 1.00 |
| 106 | PET | POLYURETHANE | BAR COATING | Ag NANOPARTICLE | SCREEN | 1.00 | 50.0 | 1.00 |
| 107 | PET | POLYURETHANE | BAR COATING | Ag NANOPARTICLE | IJ | 1.00 | 50.0 | 1.00 |
| 108 | PET | POLYURETHANE | BAR COATING | Ag NANOPARTICLE | SCREEN | 1.00 | 50.0 | 1.00 |
| 109 | PET | P-4 | IJ | Ag NANOPARTICLE | IJ | 1.00 | 50.0 | 1.00 |
| 110 | PET | P-4 | IJ(*1) | Ag NANOPARTICLE | IJ | 1.00 | 50.0 | 1.00 |
| 111 | PET | VINYL POLYMER | BAR COATING | Ag NANOPARTICLE | IJ | 1.00 | 50.0 | 1.00 |
| 112 | PET | COUPLING AGENT | BAR COATING | Ag NANOPARTICLE | IJ | 1.00 | 50.0 | 1.00 |
| 113 | PET | TiO₂ | IJ | Ag NANOPARTICLE | IJ | 1.00 | 50.0 | 1.00 |
| 114 | PET | ZnO | IJ | Ag NANOPARTICLE | IJ | 1.00 | 50.0 | 1.00 |
| 115 | PET | * 2 | IJ | Ag NANOPARTICLE | IJ | 1.00 | 50.0 | 1.00 |

| | CONDUCTIVE METAL LAYER | | | | | | | |
|---|---|---|---|---|---|---|---|---|
| | | | | TOTAL | TRANSPARENT CONDUCTIVE LAYER | | | |
| | PLATING LAYER | | | AVERAGE | | FILM | | |
| | | | THICKNESS | HEIGHT | | FORMING | THICKNESS | |
| *3 | METHOD | METAL | (μm) | (μm) | MATERIAL | METHOD | (nm) | REMARK |
| 101 | — | — | — | 1.0 | PEDOT/PSS | IJ | 150 | *4 |
| 102 | — | — | — | 1.0 | PEDOT/PSS | IJ | 150 | *4 |
| 103 | — | — | — | 1.0 | ITO | SPUTTERING | 150 | *4 |
| 104 | — | — | — | 1.0 | ITO | SPUTTERING | 150 | *4 |
| 105 | — | — | — | 1.0 | PEDOT/PSS | IJ | 150 | *5 |
| 106 | — | — | — | 1.0 | PEDOT/PSS | IJ | 150 | *5 |
| 107 | — | — | — | 1.0 | ITO | SPUTTERING | 150 | *5 |
| 108 | — | — | — | 1.0 | ITO | SPUTTERING | 150 | *5 |
| 109 | — | — | — | 1.0 | ITO | SPUTTERING | 150 | *5 |
| 110 | — | — | — | 1.0 | ITO | SPUTTERING | 150 | *5 |
| 111 | — | — | — | 1.0 | ITO | SPUTTERING | 150 | *5 |
| 112 | — | — | — | 1.0 | ITO | SPUTTERING | 150 | *5 |
| 113 | — | — | — | 1.0 | ITO | SPUTTERING | 150 | *5 |
| 114 | — | — | — | 1.0 | ITO | SPUTTERING | 150 | *5 |
| 115 | — | — | — | 1.0 | ITO | SPUTTERING | 150 | *5 |

(*1): FORMED TO BE HEIGHT OF 1 μm, LINE WIDTH OF 50 μm AND PITCH OF 1 mm ONLY ON PARTS WHERE METAL THIN WIRES ARE TO BE FORMED.
* 2: TiO₂ + MERCAPTO GROUP-CONTAINING COMPOUND
*3: TRANSPARENT ELECTRODE NO.
*4: COMPARATIVE EXAMPLE
*5: PRESENT INVENTION

TABLE 2

| | | | | CONDUCTIVE METAL LAYER | | | | |
|---|---|---|---|---|---|---|---|---|
| | | METAL ADHESION LAYER | | THIN METAL WIRE | | | | |
| | | | PRINTING | | PRINTING | HEIGHT | WIRE WIDTH | PITCH |
| *3 | SUBSTRATE | MATERIAL | METHOD | MATERIAL | METHOD | (μm) | (μm) | (mm) |
| 116 | PET | P-4 | IJ | *5 | IJ | 0.30 | 50.0 | 1.00 |
| 117 | PET | P-4 | IJ | *5 | IJ | 0.30 | 50.0 | 1.00 |
| 118 | PET | POLYURETHANE | BAR COATING | *5 | IJ | 0.30 | 50.0 | 1.00 |
| 119 | PET | VINYL POLYMER | BAR COATING | *5 | IJ | 0.30 | 50.0 | 1.00 |
| 120 | PET | Si COUPLING AGENT | BAR COATING | *5 | IJ | 0.30 | 50.0 | 1.00 |
| 121 | PET | TiO₂ | IJ | *5 | IJ | 0.30 | 50.0 | 1.00 |
| 122 | PET | ZnO | IJ | *5 | IJ | 0.30 | 50.0 | 1.00 |
| 123 | PET | *2 | IJ | *5 | IJ | 0.30 | 50.0 | 1.00 |
| 124 | PET | P-4 | IJ | *5 | IJ | 0.30 | 50.0 | 1.00 |
| 125 | PET | P-4 | IJ | *5 | IJ | 0.30 | 50.0 | 1.00 |
| 126 | PET | P-4 | IJ | *5 | IJ | 0.30 | 50.0 | 1.00 |
| 127 | PET | P-4 | IJ | *5 | IJ | 0.30 | 50.0 | 1.00 |
| 128 | PET | P-4 | IJ | *5 | SCREEN | 0.30 | 50.0 | 1.00 |
| 129 | PET | P-4 | IJ | *5 | LETTERPRESS | 0.30 | 50.0 | 1.00 |
| | | | | | REVERSE | | | |
| 130 | PET | P-4 | IJ | *5 | PARALLEL LINE | 0.06 | 5.8 | 0.07 |
| | | | | | DRAWING | | | |
| 131 | PET | P-4 | IJ | Ag COMPLEX | IJ | 0.30 | 50.0 | 1.00 |
| 132 | PET | P-4 | IJ | *5 | LETTRPRESS | 0.30 | 50.0 | 1.00 |
| | | | | | REVERSE | | | |
| 133 | PET | P-4 | IJ | Cu | IJ | 0.30 | 50.0 | 1.00 |
| | | | | NANOPARTICLE | | | | |
| 134 | PET | P-4 | IJ | *5 | IJ | 0.30 | 50.0 | 1.00 |

| | CONDUCTIVE METAL LAYER | | | | | | | |
|---|---|---|---|---|---|---|---|---|
| | | | | TOTAL | TRANSPARENT CONDUCTIVE LAYER | | | |
| | PLATING LAYER | | | AVERAGE | | FILM | | |
| | | | THICKNESS | HEIGHT | | FORMING | THICKNESS | |
| *3 | METHOD | METAL | (μm) | (μm) | MATERIAL | METHOD | (nm) | REMARK |
| 116 | *6 | Ag | 0.70 | 1.0 | PEDOT/PSS | IJ | 150 | *4 |
| 117 | *6 | Ag | 0.70 | 1.0 | ITO | SPUTTERING | 150 | *4 |
| 118 | *6 | Ag | 0.70 | 1.0 | ITO | SPUTTERING | 150 | *4 |
| 119 | *6 | Ag | 0.70 | 1.0 | ITO | SPUTTERING | 150 | *4 |
| 120 | *6 | Ag | 0.70 | 1.0 | ITO | SPUTTERING | 150 | *4 |
| 121 | *6 | Ag | 0.70 | 1.0 | ITO | SPUTTERING | 150 | *4 |
| 122 | *6 | Ag | 0.70 | 1.0 | ITO | SPUTTERING | 150 | *4 |
| 123 | *6 | Ag | 0.70 | 1.0 | ITO | SPUTTERING | 150 | *4 |
| 124 | *6 | Ag | 0.70 | 1.0 | CNT | SPUTTERING | 150 | *4 |
| 125 | ELECTROLESS | Cu | 0.70 | 1.0 | ITO | SPUTTERING | 150 | *4 |
| 126 | *6 | Cu/Ni | 0.70 | 1.0 | ITO | SPUTTERING | 150 | *4 |
| 127 | *6 | Cu | 0.70 | 1.0 | ITO | SPUTTERING | 150 | *4 |
| 128 | *6 | Ag | 0.70 | 1.0 | ITO | SPUTTERING | 150 | *4 |
| 129 | *6 | Ag | 0.70 | 1.0 | ITO | SPUTTERING | 150 | *4 |
| 130 | *6 | Cu | 0.44 | 0.5 | ITO | SPUTTERING | 150 | *4 |
| 131 | *6 | Ag | 0.70 | 1.0 | ITO | SPUTTERING | 150 | *4 |
| 132 | *6 | Ag | 0.70 | 1.0 | ITO | SPUTTERING | 150 | *4 |
| 133 | *6 | Ag | 0.70 | 1.0 | ITO | SPUTTERING | 150 | *4 |
| 134 | *6 | Cu | 0.70 | 1.0 | IZO | SPUTTERING | 150 | *4 |

*2: TiO₂ + MERCAPTO GROUP-CONTAINING COMPOUND
*3: TRANSPARENT ELECTRODE NO.
*4: PRESENT INVENTION
*5: Ag NANOPARTICLE
*6: ELECTROLYTIC

TABLE 3

| | EVALUATION RESULT | | | | | |
|---|---|---|---|---|---|---|
| | | | | STORABILITY | | |
| | SURFACE | | | CHANGE RATE IN | CHANGE RATE IN | |
| TRANSPARENT | RESISTANCE | TRANSMITTANCE | | RESISTANCE | TRANSMITTANCE | |
| ELECTRODE NO. | (Ω/□) | (%) | ADHESIVENESS | (%) | (%) | REMARK |
| 101 | 3.2 | 80 | x | 200 | 85 | *1 |
| 102 | 3.6 | 80 | x | 200 | 85 | *1 |
| 103 | 3.2 | 84 | x | 150 | 88 | *1 |
| 104 | 3.6 | 84 | x | 150 | 88 | *1 |
| 105 | 2.3 | 82 | ∘ | 115 | 92 | *2 |
| 106 | 2.8 | 82 | ∘ | 115 | 92 | *2 |
| 107 | 2.3 | 84 | ∘ | 110 | 94 | *2 |
| 108 | 2.8 | 84 | ∘ | 110 | 94 | *2 |
| 109 | 2.0 | 86 | ∘ | 105 | 96 | *2 |
| 110 | 2.3 | 86 | ∘ | 110 | 94 | *2 |
| 111 | 2.3 | 84 | ∘ | 110 | 94 | *2 |
| 112 | 2.3 | 84 | ∘ | 110 | 94 | *2 |
| 113 | 2.3 | 84 | ∘ | 110 | 94 | *2 |
| 114 | 2.3 | 84 | ∘ | 110 | 94 | *2 |
| 115 | 2.3 | 84 | ∘ | 110 | 94 | *2 |
| 116 | 1.4 | 84 | ∘ | 108 | 96 | *2 |
| 117 | 1.4 | 86 | ∘ | 105 | 96 | *2 |
| 118 | 1.6 | 84 | ∘ | 108 | 94 | *2 |
| 119 | 1.6 | 84 | ∘ | 108 | 94 | *2 |
| 120 | 1.6 | 84 | ∘ | 108 | 94 | *2 |
| 121 | 1.6 | 84 | ∘ | 108 | 94 | *2 |
| 122 | 1.6 | 84 | ∘ | 108 | 94 | *2 |
| 123 | 1.6 | 84 | ∘ | 108 | 94 | *2 |
| 124 | 1.4 | 86 | ∘ | 108 | 94 | *2 |
| 125 | 1.4 | 86 | ∘ | 105 | 96 | *2 |
| 126 | 1.4 | 86 | ∘ | 105 | 96 | *2 |
| 127 | 1.4 | 86 | ∘ | 105 | 96 | *2 |
| 128 | 1.4 | 86 | ∘ | 105 | 96 | *2 |
| 129 | 1.4 | 86 | ∘ | 105 | 96 | *2 |
| 130 | 1.4 | 86 | ∘ | 105 | 96 | *2 |
| 131 | 1.4 | 86 | ∘ | 105 | 96 | *2 |
| 132 | 1.4 | 86 | ∘ | 105 | 96 | *2 |
| 133 | 1.4 | 86 | ∘ | 105 | 96 | *2 |
| 134 | 1.4 | 86 | ∘ | 102 | 98 | *2 |

*1: COMPARATIVE EXAMPLE
*2: PRESENT INVENTION

<<Evaluation Results>>

By comparing the transparent electrodes 101 to 104 with the transparent electrodes 105 to 134, it is understood that providing the metal adhesion layer can produce a transparent electrode having low resistance and high adhesiveness and also having excellent storability.

Further, by comparing the transparent electrodes 105 to 115 with the transparent electrodes 116 to 134, it is understood that use of plating archives lower resistance even when they are the same in the total average height of the conductive metal layer.

Still further, by comparing the transparent electrodes 105 and 106 with the transparent electrodes 107 and 108, it is understood that use of ITO as the transparent conductive layer archives higher transmittance and more excellent storability.

### Second Example

### <<Manufacture of Organic EL Elements>>

### (Formation of Layers)

Using the manufactured transparent electrodes 101 to 134, organic EL elements 201 to 234 were manufactured, respectively, as described below.

Note that the samples dried in the glovebox were carried to a vapor-deposition device without being exposed to the air, and the substrates were set therein.

Further, the samples dried in the vacuum layer were carried in vacuum to a vacuum layer for vapor deposition, and the substrates were set therein.

Vapor-deposition crucibles of a vacuum deposition device were filled with constitutive materials for the respective layers at their respective optimum amounts to manufacture each element. The vapor-deposition crucibles used were made of a material for resistance heating such as molybdenum or tungsten.

Structural formulae of compounds used in this Example are shown below.

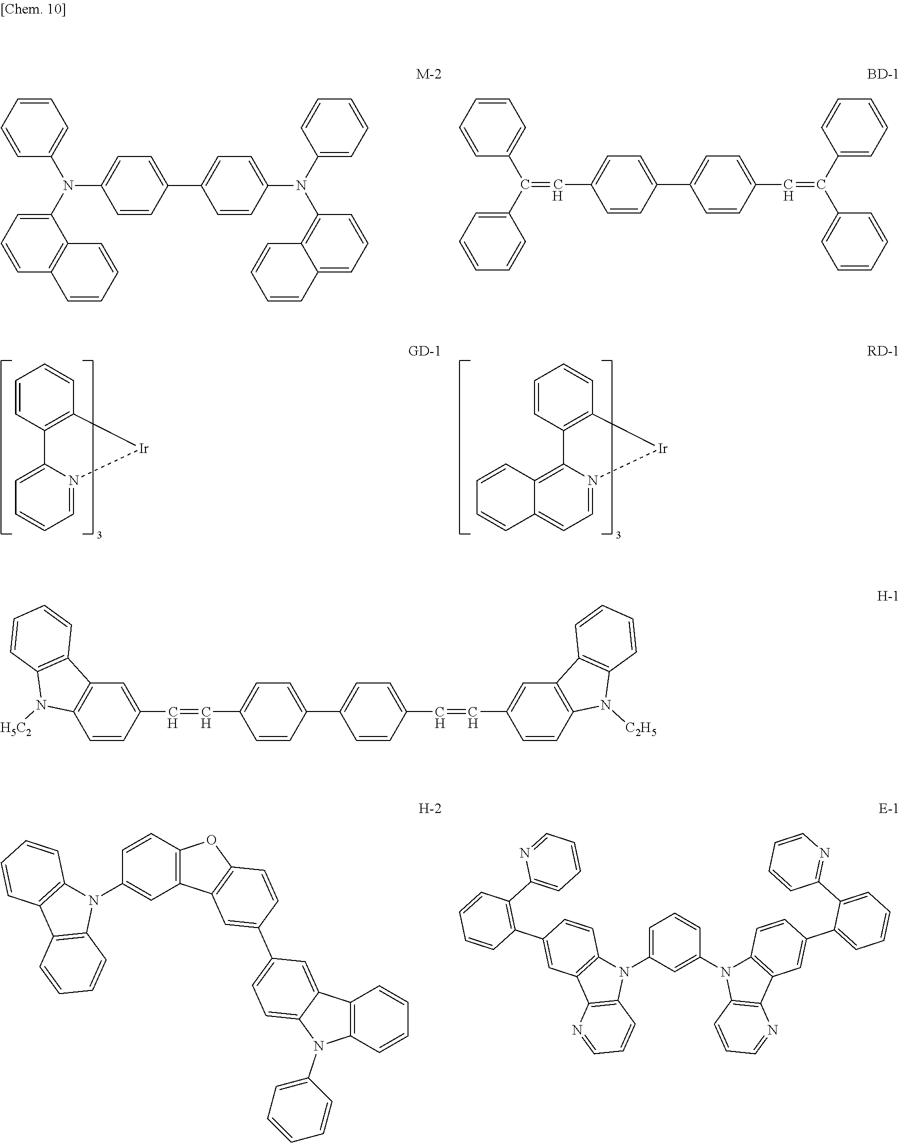

After the pressure was reduced to a vacuum of 1×10⁻⁴ Pa, the vapor-deposition crucible having Compound M-2 therein was electrically heated, and Compound M-2 was deposited on each manufactured transparent substrate at a deposition rate of 0.1 nm/sec. Thus, a positive hole injection-transport layer having a thickness of 40 nm was formed.

Next, Compounds BD-1 and H-1 were co-deposited at a deposition rate of 0.1 nm/sec. in such a way that the concentration of Compound BD-1 was 5 percent by volume. Thus, a blue florescent layer having a thickness of 15 nm was formed.

Next, Compounds GD-1, RD-1 and H-2 were co-deposited at a deposition rate of 0.1 nm/sec. in such a way that the concentration of Compound GD-1 was 17 percent by volume, and the concentration of Compound RD-1 was 0.8 percent by volume. Thus, a yellow phosphorescent layer having a thickness of 15 nm was formed.

Thereafter, Compound E-1 was deposited at a deposition rate of 0.1 nm/sec. Thus, an electron transport layer having a thickness of 30 nm was formed.

Further, after LiF was formed to be a thickness of 1.5 nm, aluminum was deposited to be 110 nm. Thus, a cathode was formed.

(Sealing)

### <Preparation of Adhesive Composition>

100 parts by mass of “Oppanol B50 (manufactured by BASF, Mw: 340,000)” as a polyisobutylene resin, 30 parts by mass of “Nisseki Polybutene Grade HV-1900 (manufactured by Nippon Oil Corporation, Mw: 1,900)” as a polybutene resin, 0.5 parts by mass of “TINUVIN 765 (manufactured by BASF Japan, having a tertiary hindered amine group)” as a hindered amine light stabilizer, 0.5 parts by mass of “IRGANOX 1010 (manufactured by BASF Japan, both of β positions of a hindered phenol group have tertiary butyl groups)” as a hindered phenol antioxidant, and 50 parts by mass of “Eastotac H-100L Resin (manufactured by Eastman Chemical Company)” as a cyclic olefin polymer were dissolved in toluene. Thus, an adhesive composition having a solid content concentration of about 25 percent by mass was prepared.

<Manufacture of Sealing Member>

First, a polyethylene terephthalate film having a thickness of 50 μm with an aluminum (Al) foil having a thickness of 100 μm attached was prepared as a sealing base material.

Next, a solution of the prepared adhesive composition was applied to the aluminum side (gas barrier layer side) of the sealing base material in such a way that the thickness of an adhesive layer to be formed after being dried was 20 μm, and dried at 120° C. for two minutes. Thus, an adhesive layer was formed.

Next, to the surface of the formed adhesive layer, a surface of a polyethylene terephthalate film having a thickness of 38 μm, the surface being release-treated, was attached as a release sheet. Thus, a sealing member was produced.

Thus-produced sealing member was left for 24 hours or more in a nitrogen atmosphere.

Thereafter, the release sheet was removed, and laminating was carried out in such a way as to cover the formed cathode with a vacuum laminator heated to 80° C. Further, heating was carried out at 120° C. for 30 minutes, so that sealing was carried out.

With respect to the manufactured organic EL elements 201 to 234, the following evaluations were carried out. The evaluation results are shown in TABLE 4.

<<Evaluation Methods>>

### (1) Luminance and Voltage

A current of 50 A/m² was made to follow through each organic EL element, so that each organic EL element emitted light. As a current source, 6243 manufactured by ADC Corporation was used. Also, voltage was measured with 6243 manufactured by ADC Corporation.

Luminance was measured at the center with a spectroradiometer CS-2000 (manufactured by Konica Minolta, Inc.). For measurement of luminance, distance from the spectroradiometer was adjusted, and the measurement area was made to be φ3 mm.

Luminance and voltage are each shown as a relative value, taking the organic EL element 201 as a reference.

### (2) Measurement of Storability (Change Rate in Luminance)

Luminance was measured before and after each organic EL element was stored for 250 hours in a thermostat oven of 85° C. (humidity of 4% or less).

The change rate in luminance was obtained as follows.

Change Rate in Luminance (%)=(Luminance after Storing at 85° C.)/(Luminance before Storing at 85° C.)×100

TABLE 4

| ORGANIC | | EVALUATION RESULT | | | |
|---|---|---|---|---|---|
| EL | | LUMINANCE | VOLTAGE | STORABILITY | |
| ELEMENT | TRANSPARENT | (RELATIVE | (RELATIVE | CHANGE RATE IN | |
| NO. | ELECTRODE NO. | VALUE) | VALUE) | LUMINANCE (%) | REMARK |
| 201 | 101 | 100 | 100 | 60 | COMPARATIVE EXAMPLE |
| 202 | 102 | 98 | 102 | 60 | COMPARATIVE EXAMPLE |
| 203 | 103 | 100 | 100 | 60 | COMPARATIVE EXAMPLE |
| 204 | 104 | 98 | 102 | 60 | COMPARATIVE EXAMPLE |
| 205 | 105 | 113 | 93 | 87 | PRESENT INVENTION |
| 206 | 106 | 110 | 95 | 85 | PRESENT INVENTION |
| 207 | 107 | 113 | 93 | 87 | PRESENT INVENTION |
| 208 | 108 | 110 | 98 | 82 | PRESENT INVENTION |
| 209 | 109 | 115 | 90 | 90 | PRESENT INVENTION |
| 210 | 110 | 113 | 93 | 87 | PRESENT INVENTION |
| 211 | 111 | 113 | 93 | 87 | PRESENT INVENTION |
| 212 | 112 | 113 | 93 | 87 | PRESENT INVENTION |
| 213 | 113 | 113 | 93 | 87 | PRESENT INVENTION |
| 214 | 114 | 113 | 93 | 87 | PRESENT INVENTION |
| 215 | 115 | 113 | 93 | 87 | PRESENT INVENTION |
| 216 | 116 | 120 | 86 | 94 | PRESENT INVENTION |
| 217 | 117 | 120 | 86 | 94 | PRESENT INVENTION |
| 218 | 118 | 118 | 84 | 96 | PRESENT INVENTION |
| 219 | 119 | 118 | 84 | 96 | PRESENT INVENTION |
| 220 | 120 | 118 | 84 | 96 | PRESENT INVENTION |
| 221 | 121 | 118 | 84 | 96 | PRESENT INVENTION |
| 222 | 122 | 118 | 84 | 96 | PRESENT INVENTION |
| 223 | 123 | 118 | 84 | 96 | PRESENT INVENTION |
| 224 | 124 | 120 | 86 | 94 | PRESENT INVENTION |
| 225 | 125 | 120 | 86 | 94 | PRESENT INVENTION |
| 226 | 126 | 120 | 86 | 94 | PRESENT INVENTION |
| 227 | 127 | 120 | 86 | 94 | PRESENT INVENTION |
| 228 | 128 | 120 | 86 | 94 | PRESENT INVENTION |
| 229 | 129 | 120 | 86 | 94 | PRESENT INVENTION |
| 230 | 130 | 120 | 86 | 94 | PRESENT INVENTION |
| 231 | 131 | 120 | 86 | 94 | PRESENT INVENTION |
| 232 | 132 | 120 | 86 | 94 | PRESENT INVENTION |
| 233 | 133 | 120 | 86 | 94 | PRESENT INVENTION |
| 234 | 134 | 120 | 84 | 96 | PRESENT INVENTION |

### <<Evaluation Results>>

By comparing the organic EL elements 201 to 204 with the organic EL elements 205 to 234, it is understood that the transparent electrode provided with the metal adhesion layer can produce an organic EL element having high luminance and low voltage and also having excellent storability.

Further, by comparing the transparent electrodes 205 to 215 with the transparent electrodes 216 to 234, it is understood that use of plating archives higher luminance and lower voltage and also improves storability even when they are the same in the total average height of the conductive metal layer.

### INDUSTRIAL APPLICABILITY

As described above, the present invention is suited to provide a transparent electrode having low resistance and high storability, a method for manufacturing the transparent electrode and an organic EL element provided with the transparent electrode.

### DESCRIPTION OF REFERENCE NUMERALS

10 Transparent Electrode
11 Substrate
12 Conductive Metal Layer
13 Thin Metal Wire
14 Plating Layer
15 Transparent Conductive Layer
16, 16a, 16b Metal Adhesion Layer
70 Organic EL Element
71 Counter Electrode
72 Organic Functional Layer
73 Extraction Electrode
74 Sealing Member

1. A transparent electrode comprising:
a substrate;
a conductive metal layer on the substrate;
a metal adhesion layer between the substrate and the conductive metal layer; and
a transparent conductive layer covering the substrate, the metal adhesion layer and the conductive metal layer, wherein
the conductive metal layer has a thin metal wire formed using a metal nanoparticle ink or a metal complex ink.

2. The transparent electrode according to claim 1, wherein the conductive metal layer further has a plating layer covering the thin metal wire.

3. The transparent electrode according to claim 1, wherein the thin metal wire is formed by printing.

4. The transparent electrode according to claim 1, wherein the thin metal wire is formed using an inkjet parallel line drawing method.

5. The transparent electrode according to claim 1, wherein the metal adhesion layer contains a nitrogen atom-containing compound.

6. The transparent electrode according to claim 5, wherein polyurethane is contained as the nitrogen atom-containing compound.

7. The transparent electrode according to claim 5, wherein
the metal adhesion layer is formed using a curable composition, and
the curable composition contains, as the mitogen atom-containing compound, an aromatic heterocyclic compound containing a nitrogen atom having an unshared electron pair uninvolved in aromaticity.

8. The transparent electrode according to claim 1, wherein the metal adhesion layer contains a vinyl polymer.

9. The transparent electrode according to claim 1, wherein the metal adhesion layer contains a coupling agent.

10. The transparent electrode according to claim 1, wherein the metal adhesion layer contains a metal oxide.

11. The transparent electrode according to claim 10, wherein the metal adhesion layer further contains a mercapto group-containing compound.

12. The transparent electrode according to claim 1, wherein the transparent conductive layer contains a conductive polymer.

13. The transparent electrode according to claim 1, wherein the transparent conductive layer contains a transparent conductive metal oxide.

14. A method for manufacturing a transparent electrode, comprising:
forming a metal adhesion layer on a substrate;
forming a thin metal wire on the metal adhesion layer using a metal nanoparticle ink or a metal complex ink, thereby forming a conductive metal layer; and
forming a transparent conductive layer on the substrate, the metal adhesion layer and the conductive metal layer.

15. An organic electroluminescence element comprising the transparent electrode according to claim 1.
